(19) United States
(12) Patent Application Publication
(10) Pub. No.: US 2025/0048623 A1
(43) Pub. Date: Feb. 6, 2025

(54) ONE-TIME-PROGRAMMABLE MEMORY ARRAY HAVING DIFFERENT DEVICE CHARACTERISTICS AND METHODS OF MANUFACTURING THEREOF

(71) Applicant: Taiwan Semiconductor Manufacturing Company, Ltd., Hsinchu (TW)

(72) Inventors: Yu-Wei Lin, Hsinchu (TW); Meng-Sheng Chang, Hsinchu (TW)

(73) Assignee: Taiwan Semiconductor Manufacturing Company, Ltd., Hsinchu (TW)

(21) Appl. No.: 18/410,734

(22) Filed: Jan. 11, 2024

Related U.S. Application Data
(60) Provisional application No. 63/517,782, filed on Aug. 4, 2023.

(51) Int. Cl. H10B 20/25

(52) U.S. Cl. CPC H10B 20/25

(57) ABSTRACT

A memory device includes a plurality of one-time-programming (OTP) memory cells grouped at least into a first portion and a second portion, wherein the first and second portions are disposed next to each other along a first lateral direction; a first driver circuit disposed next to the first portion along a first lateral direction, wherein the first portion is interposed between the second portion and the first driver circuit along the first lateral direction; and a second driver circuit disposed next to both of the first and second portions along a second lateral direction perpendicular to the first lateral direction. The OTP memory cells of the first portion are associated with a first electrical/physical characteristic and the OTP memory cells of the second portion are associated with a second electrical/physical characteristic, in which the first electrical/physical characteristic is different from the second electrical/physical characteristic.

### CROSS-REFERENCE TO RELATED APPLICATION

This application claims priority to and the benefit of U.S. Provisional Application No. 63/517,782, filed Aug. 4, 2023, entitled “ULTRA HIGH DENSITY EFUSE MEMORY,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory device, in accordance with some embodiments.

FIG. 2 illustrates an example schematic diagram of an efuse memory cell of the memory device of FIG. 1, in accordance with some embodiments.

FIG. 3 illustrates an example arrangement of a memory array of the memory device of FIG. 1, in accordance with some embodiments.

FIG. 4 illustrates another example arrangement of a memory array of the memory device of FIG. 1, in accordance with some embodiments.

FIG. 5 illustrates yet another example arrangement of a memory array of the memory device of FIG. 1, in accordance with some embodiments.

FIG. 6 illustrates an example arrangement of a memory device including a number of memory arrays, in accordance with some embodiments.

FIG. 7 illustrates a cross-sectional view of an example semiconductor device including an efuse memory cell and a peripheral component, in accordance with some embodiments.

FIG. 8 illustrates a cross-sectional view of another example semiconductor device including a first efuse memory cell, a second efuse memory cell, and a peripheral component, in accordance with some embodiments.

FIG. 9 illustrates a cross-sectional view of an example BEOL transistor, in accordance with some embodiments.

FIG. 10 illustrates a cross-sectional view of another example BEOL transistor, in accordance with some embodiments.

FIGS. 11 and 12 collectively illustrate an example layout for forming an efuse memory cell, in accordance with some embodiments.

FIGS. 13 and 14 collectively illustrate another example layout for forming an efuse memory cell, in accordance with some embodiments.

FIG. 15 illustrate an example layout for forming a plural number of efuse memory arrays, in accordance with some embodiments.

FIG. 16 illustrates a flow chart of an example method for fabricating a memory device, in accordance with some embodiments.

FIG. 17 illustrates a flow chart of an example method for fabricating access transistors with respectively different electrical characteristics, in accordance with some embodiments.

FIG. 18 illustrates a flow chart of an example method for fabricating access transistors with respectively different physical characteristics, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Developments in electronic devices, such as computers, portable devices, smart phones, internet of thing (IoT) devices, etc., have prompted increased demands for memory devices. In general, memory devices may be volatile memory devices and non-volatile memory devices. Volatile memory devices can store data while power is provided but may lose the stored data once the power is shut off. Unlike volatile memory devices, non-volatile memory devices may retain data even after the power is shut off but may be slower than the volatile memory devices.

A one-time-programmable (OTP) memory device is one type of the non-volatile memory device utilized in integrated circuits for adjusting the circuitry after fabrication of an integrated circuit. For example, the OTP memory device is used for providing repair information that controls the usage of redundant cells in replacing defective cells of a memory array. Another use is for tuning analog circuitry by trimming a capacitive or resistive value of an analog circuit or enabling and disabling portions of the system. A recent trend is that the same product is likely to be manufactured in different fabrication facilities though in a common process technology. Despite best engineering efforts, it is likely that each facility will have a slightly different process. Usage of OTP memory devices allows independent optimization of the product functionality for each manufacturing facility.

As the technologies of integrated circuits advance, integrated circuit features (e.g., transistor gate length) have been decreasing, thereby allowing for more circuitry to be implemented in an integrated circuit. Accordingly, an OTP memory device can include an increasing number (or density) of OTP memory cells. Example OTP memory cells include a fuse, sometimes referred as an electronic fuse (efuse). Such OTP memory cells are typically arranged as an array, with a number of rows and a number of columns intersecting with one another. Each of the OTP memory cells can be accessed (e.g., read, programmed) though the respective combination of a bit line (BL) and a word line (WL). The array thus includes a plural number of such WLs and BLs disposed along the rows and columns, respectively. The increasing number of the cells generally result in high voltage (IR) drop presented on the WL/BL, which disadvantageously impacts performance of the OTP memory device. Thus, the existing OTP memory devices have not been entirely satisfactory in certain aspects.

The present disclosure provides various embodiments of a memory device including at least one OTP memory array that consists of multiple portions, memory cells of at least two of the portions having respectively different electrical/physical characteristics. In various embodiments of the present disclosure, the memory cell of the OTP memory array may be an efuse cell, which includes a fuse resistor and a transistor connected in series to each other. In one aspect of the present disclosure, the memory cells of a first portion of the memory array can have their respective transistors configured with a first threshold voltage, and the memory cells of a second portion of the memory array can have their respective transistors configured with a second threshold voltage. The first threshold voltage is different from the second threshold voltage. In another aspect of the present disclosure, the memory cells of a first portion of the memory array can have their respective transistors formed in a front-end-of-line (FEOL) network, and the memory cells of a second portion of the memory array can have their respective transistors formed in a back-end-of-line (BEOL) network.

According to various embodiments of the present disclosure, the first portion may be disposed closer to an input/output (I/O) circuit or otherwise driver circuit of the memory device, while the second portion may be disposed farther from the I/O circuit or otherwise driver circuit. The first portion and the second portion may sometimes be referred to as “near portion” and “far portion,” respectively. By configuring the memory cells in different portions with respective electrical/physical characteristics, the effect of an IR drop caused by the large physical distance from the I/O circuit or otherwise driver circuit (due to the long WL/BL) can be significantly mitigated. For example, even with the presence of an IR drop, the memory cells in the far portion (e.g., with a smaller threshold voltage) can be turned on relatively easier than the memory cells in the near portion (e.g., with a higher threshold voltage), which, in turn, can compensate for such an IR drop. In another example, by forming the transistors of the memory cells in the far portion in the BEOL network, a shorter conduction path from their respective fuse resistors to the transistors can be formed, thereby compensating for any potential IR drop that may be incurred for the transistors in the far portion.

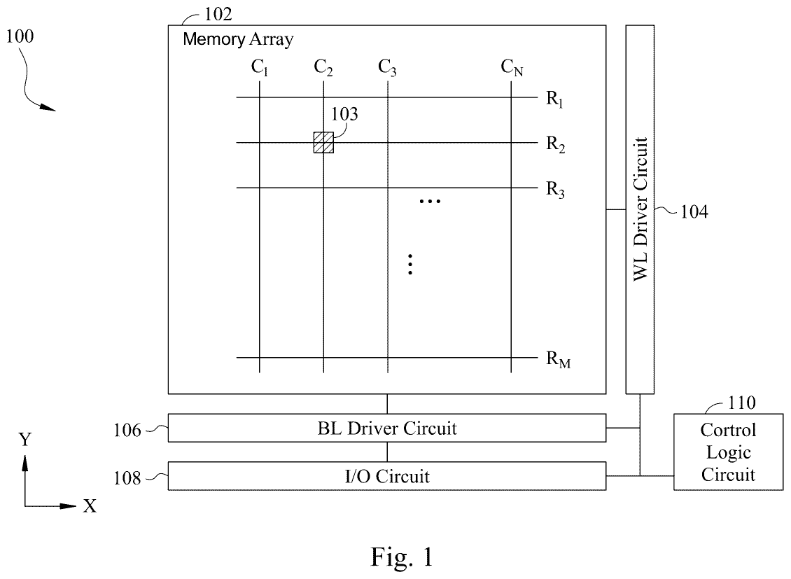

FIG. 1 illustrates a block diagram of a memory device 100, in accordance with various embodiments. As shown, the memory device 100 includes a memory array 102, a WL driver circuit 104, a BL driver circuit 106, an input/output (I/O) circuit 108, and a control logic circuit 110. Despite not being shown in FIG. 1, the components of the memory device 100 may be operatively coupled to each other and to the control logic circuit 112. Although, in the illustrated embodiment of FIG. 1, each component is shown as a separate block for the purpose of clear illustration, in some other embodiments, some or all of the components shown in FIG. 1 may be integrated together. For example, the memory array 102 may include an embedded I/O circuit 108.

The memory array 102 is a hardware component that stores data. In one aspect, the memory array 102 is embodied as a semiconductor memory device. The memory array 102 includes a plurality of memory cells (or otherwise storage units) 103. The memory array 102 includes a number of rows R₁, R₂, R₃ . . . . R_{M}, each extending in a first direction (e.g., X-direction) and a number of columns C₁, C₂, C₃ . . . . C_{N}, each extending in a second direction (e.g., Y-direction). Each of the rows/columns may include one or more conductive structures. For example, each column may include at least one bit line (BL), and each row may include at least one word line (WL). In some embodiments, each memory cell 103 is arranged in the intersection of a corresponding row and a corresponding column, and can be operated according to a voltage or current signal conducted through the BL disposed in that column and the WL of disposed in that row.

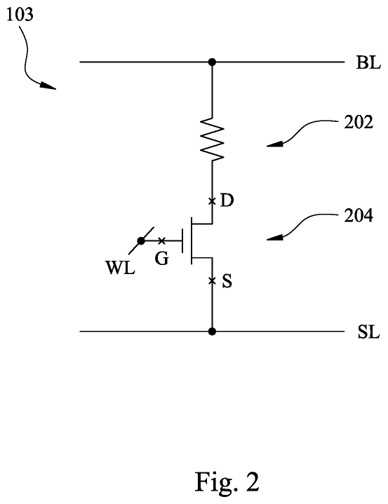

In accordance with various embodiments of the present disclosure, each memory cell 103 is implemented as an efuse cell that includes a fuse resistor and an access transistor coupled to each other in series. The access transistor can be coupled to (e.g., gated by) a corresponding WL. The access transistor can be turned on/off to enable/disable an access (e.g., program, read) to the corresponding fuse resistor. For example, upon being selected, the access transistor of the selected fuse cell is turned on to generate a program or read path conducting through its fuse resistor and itself. Detailed descriptions on configurations of the memory cell 103 will be discussed below with respect to FIG. 2.

The WL driver circuit 104 is a hardware component that can receive a row address of the memory array 102 and assert a WL associated with that row address. The BL driver circuit 106 is a hardware component that can receive a column address of the memory array 102 and assert a BL associated with that column address. The I/O circuit 108 is a hardware component that can access (e.g., read, program) each of the memory cells 103 asserted through the WL driver circuit 104 and BL driver circuit 106. The control logic circuit 110 is a hardware component that can control the coupled components (e.g., 102 through 108).

FIG. 2 illustrates an example configuration of the efuse cell 103 (FIG. 1), in accordance with various embodiments. The efuse cell 103 is implemented as a 1T1R configuration, for example, a fuse resistor 202 serially connected to an access transistor 204. It, however, should be understood that any of various other fuse configurations that exhibit the fuse characteristic may be used by the efuse cell 103 such as, for example, a 2-diodes-1-resistor (2D1R) configuration, a many-transistors-one-resistor (manyT1R) configuration, etc., while remaining within the scope of the present disclosure.

In various embodiments, the fuse resistor 202 may be formed of one or more metal lines. For example, the fuse resistor 202 may be one of a number of interconnect structures in one of a number metallization layers that are disposed above the access transistor 204. In one aspect of the present disclosure, the access transistor 204 may be formed along a major surface of a semiconductor substrate, which is sometimes referred to as part of front-end-of-line (FEOL) processing/network. Over the FEOL network, a number of metallization layers, each of which includes a number of interconnect (e.g., metal) structures, are typically formed, which are sometimes referred to as part of back-end-of-line (BEOL) processing/network. In another aspect of the present disclosure, the access transistor 204 may also be formed through/in the BEOL network.

With the fuse resistor 202 (of the efuse cell 103) embodied as a metal line, the fuse resistor 202 may present an initial resistance value (or resistivity), for example, as fabricated. To program the efuse cell 103, the access transistor 204 (if embodied as an n-type transistor) is turned on by applying a (e.g., voltage) signal, corresponding to a logic high state, through a word line (WL) to a gate terminal of the access transistor 204. Concurrently or subsequently, a high enough (e.g., voltage) signal is applied on one of the terminals of the fuse resistor 202 through a bit line (BL). With the access transistor 204 turned on to provide a (e.g., program) path from the BL, through the resistor 202 and transistor 204, and to a source line (SL) typically tied to ground, such a high voltage signal can burn out a portion of the corresponding metal line (the fuse resistor 202), thereby transitioning the fuse resistor 202 from a first state (e.g., a short circuit) to a second state (e.g., an open circuit). Accordingly, the efuse cell 103 can irreversibly transition from a first logic state (e.g., logic 0) to a second logic state (e.g., logic 1), which can be read out by applying a relatively low voltage signal on the BL and turning on the access transistor 204 to provide a (e.g., read) path.

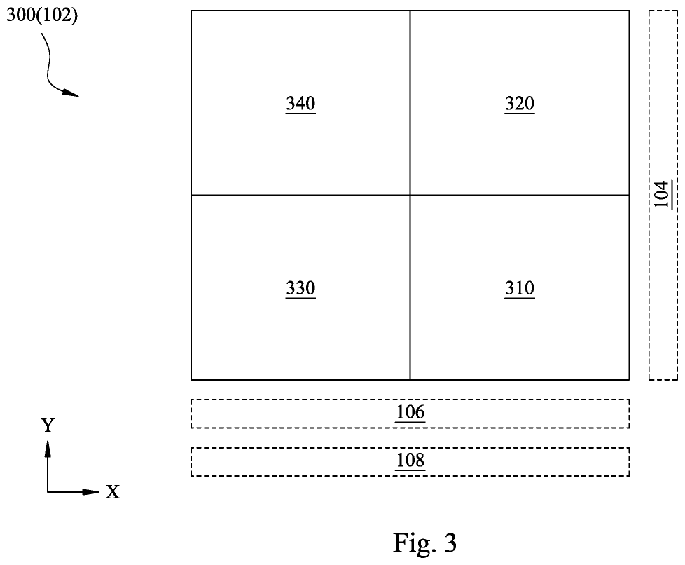

FIGS. 3, 4, and 5 illustrate a first arrangement 300, a second arrangement 400, and a third arrangement 500 of different portions of the memory array 102, respectively, in accordance with various embodiments. The different portions may correspond to the access transistors of the memory cells disposed therein having their own respective electrical/physical characteristics. As used herein, the electrical characteristic of an access transistor may correspond to one or more operation-wise properties of the access transistor (e.g., a threshold voltage of the access transistor); and the physical characteristic of an access transistor may correspond to one or more fabrication-wise properties of the access transistor (e.g., a FEOL or BEOL network in/through which the access transistor is formed).

In FIG. 3, the first arrangement 300 separates the memory array 102 into four portions, 310, 320, 330, and 340. As shown, the portion 310 is disposed immediately next to the WL driver circuit 104 along the X-direction and to the BL driver circuit 106 along the Y-direction; the portion 320 is disposed immediately next to the WL driver circuit 104 along the X-direction, and next to the BL driver circuit 106 along the Y-direction with the portion 310 interposed therebetween; the portion 330 is disposed immediately next to the BL driver circuit 106 along the Y-direction, and next to the WL driver circuit 104 along the X-direction with the portion 310 interposed therebetween; and the portion 340 is disposed next to the BL driver circuit 106 along the Y-direction with the portion 330 interposed therebetween, and next to the WL driver circuit 104 along the X-direction with the portion 320 interposed therebetween. With respect to the BL driver circuit 106 (and the I/O circuit 108), each of the portions 310 and 330 may sometimes be referred to as the near portion, and each of the portions 320 and 340 may sometimes be referred to as the far portion. In various embodiments, the four portions 310 to 340 may have the same size, e.g., the same number of memory cells.

According to one aspect of the present disclosure, the access transistors (of the memory cells) in the portion 310 may have a first threshold voltage; the access transistors (of the memory cells) in the portion 320 may have a second threshold voltage; the access transistors (of the memory cells) in the portion 330 may have a third threshold voltage; and the access transistors (of the memory cells) in the portion 340 may have a fourth threshold voltage. In some embodiments, the fourth threshold voltage is substantially less than the third threshold voltage, which is equal to the second threshold voltage, which is substantially less than the first threshold voltage. As a non-limiting example, the first threshold voltage may be in the range of about 0.25 volts (V), the second and third threshold voltages may each be less than the first threshold voltage by about 40˜80 millivolts (mV), and the fourth threshold voltage may be less than the second/third threshold voltage by about 40˜80 mV.

According to another aspect of the present disclosure, the access transistors (of the memory cells) in the portion 310 may be formed in a FEOL network (e.g., along the major surface of a corresponding substrate); the access transistors (of the memory cells) in the portion 320 may be formed in a BEOL network (e.g., in one or more metallization layers disposed over the major surface of the corresponding substrate); the access transistors (of the memory cells) in the portion 330 may be formed in the FEOL network; and the access transistors (of the memory cells) in the portion 340 may be formed in the BEOL network. As a non-limiting example, the FEOL transistors (e.g., the access transistors in the portions 310 and 330) may each be implemented as a number of sub-transistors connected in parallel. These FEOL sub-transistors may each be configured as a planar transistor structure, a fin-based transistor structure, or a gate-all-around transistor structure, with a group IV element (e.g., silicon, germanium) or a group III-V element (e.g., gallium arsenic, indium arsenic) serving as its channel material. The BEOL transistors (e.g., the access transistors in the portions 320 and 340) may each be implemented as a number of sub-transistors connected in parallel. These BEOL sub-transistors may each be configured as a thin-film transistor structure or back-gate transistor structure, with a semiconductive-behaving oxide material (e.g., IGZO, InZnO, InSnO, SnO₂, MgAlZnO, CuO, SnO, oxides of the Delafossite group Cu—X—O with or without doping, or combinations thereof) serving as its channel material.

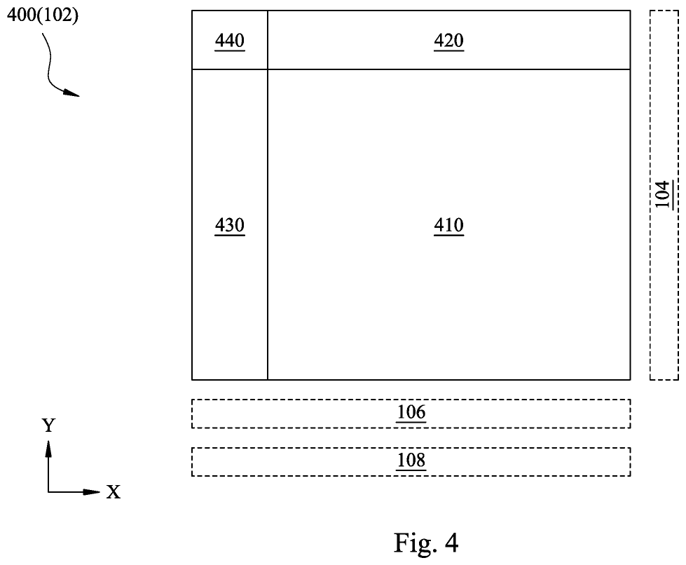

In FIG. 4, the second arrangement 400 separates the memory array 102 into four portions, 410, 420, 430, and 440. As shown, the portion 410 is disposed immediately next to the WL driver circuit 104 along the X-direction and to the BL driver circuit 106 along the Y-direction; the portion 420 is disposed immediately next to the WL driver circuit 104 along the X-direction, and next to the BL driver circuit 106 along the Y-direction with the portion 410 interposed therebetween; the portion 430 is disposed immediately next to the BL driver circuit 106 along the Y-direction, and next to the WL driver circuit 104 along the X-direction with the portion 410 interposed therebetween; and the portion 440 is disposed next to the BL driver circuit 106 along the Y-direction with the portion 430 interposed therebetween, and next to the WL driver circuit 104 along the X-direction with the portion 420 interposed therebetween. With respect to the BL driver circuit 106 (and the I/O circuit 108), each of the portions 410 and 430 may sometimes be referred to as the near portion, and each of the portions 420 and 440 may sometimes be referred to as the far portion. In various embodiments, the four portions 410 to 440 may have different sizes, e.g., different numbers of memory cells. For example, the portion 410 is larger than the portion 420, which is about the same as the portion 430, which is larger than the portion 440.

According to one aspect of the present disclosure, the access transistors (of the memory cells) in the portion 410 may have a first threshold voltage; the access transistors (of the memory cells) in the portion 420 may have a second threshold voltage; the access transistors (of the memory cells) in the portion 430 may have a third threshold voltage; and the access transistors (of the memory cells) in the portion 440 may have a fourth threshold voltage. In some embodiments, the fourth threshold voltage is substantially less than the third threshold voltage, which is equal to the second threshold voltage, which is substantially less than the first threshold voltage. As a non-limiting example, the first threshold voltage may be in the range of about 0.25 volts (V), the second and third threshold voltages may each be less than the first threshold voltage by about 40˜80 millivolts (mV), and the fourth threshold voltage may be less than the second/third threshold voltage by about 40˜80 mV.

According to another aspect of the present disclosure, the access transistors (of the memory cells) in the portion 410 may be formed in a FEOL network (e.g., along the major surface of a corresponding substrate); the access transistors (of the memory cells) in the portion 420 may be formed in a BEOL network (e.g., in one or more metallization layers disposed over the major surface of the corresponding substrate); the access transistors (of the memory cells) in the portion 430 may be formed in the FEOL network; and the access transistors (of the memory cells) in the portion 440 may be formed in the BEOL network. As a non-limiting example, the FEOL transistors (e.g., the access transistors in the portions 410 and 430) may each be implemented as a number of sub-transistors connected in parallel. These FEOL sub-transistors may each be configured as a planar transistor structure, a fin-based transistor structure, or a gate-all-around transistor structure, with a group IV element (e.g., silicon, germanium) or a group III-V element (e.g., gallium arsenic, indium arsenic) serving as its channel material. The BEOL transistors (e.g., the access transistors in the portions 420 and 440) may each be implemented as a number of sub-transistors connected in parallel. These BEOL sub-transistors may each be configured as a thin-film transistor structure or back-gate transistor structure, with a semiconductive-behaving oxide material (e.g., IGZO, InZnO, InSnO, SnO₂, MgAlZnO, CuO, SnO, oxides of the Delafossite group Cu—X—O with or without doping, or combinations thereof) serving as its channel material.

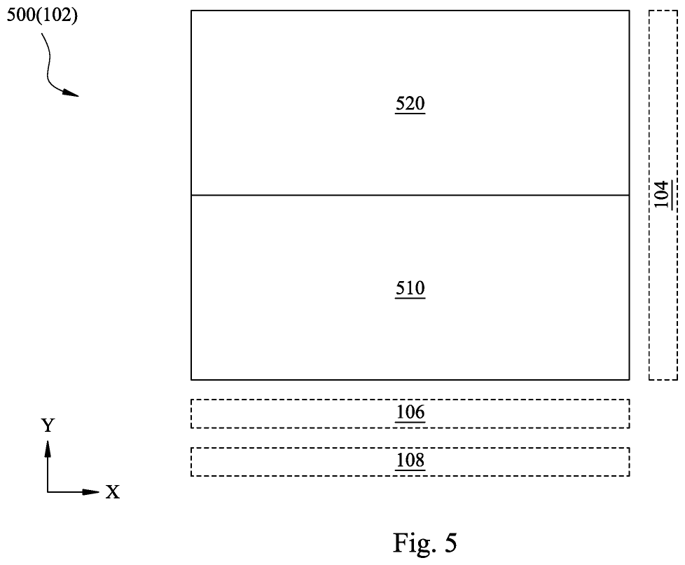

In FIG. 5, the third arrangement 500 separates the memory array 102 into two portions, 510 and 520. As shown, the portion 510 is disposed immediately next to the WL driver circuit 104 along the X-direction and to the BL driver circuit 106 along the Y-direction; and the portion 520 is disposed immediately next to the WL driver circuit 104 along the X-direction, and next to the BL driver circuit 106 along the Y-direction with the portion 510 interposed therebetween. With respect to the BL driver circuit 106 (and the I/O circuit 108), the portion 510 may sometimes be referred to as the near portion, and the portion 520 may sometimes be referred to as the far portion. In various embodiments, the four portions 510 to 520 may have the same size, e.g., the same number of memory cells, or different sizes, e.g., different numbers of memory cells.

According to one aspect of the present disclosure, the access transistors (of the memory cells) in the portion 510 may have a first threshold voltage; and the access transistors (of the memory cells) in the portion 520 may have a second threshold voltage. In some embodiments, the second threshold voltage is substantially less than the first threshold voltage. As a non-limiting example, the first threshold voltage may be in the range of about 0.25 volts (V), and the second threshold voltage may each be less than the first threshold voltage by about 40˜80 millivolts (mV).

According to another aspect of the present disclosure, the access transistors (of the memory cells) in the portion 510 may be formed in a FEOL network (e.g., along the major surface of a corresponding substrate); and the access transistors (of the memory cells) in the portion 520 may be formed in a BEOL network (e.g., in one or more metallization layers disposed over the major surface of the corresponding substrate). As a non-limiting example, the FEOL transistors (e.g., the access transistors in the portion 510) may each be implemented as a number of sub-transistors connected in parallel. These FEOL sub-transistors may each be configured as a planar transistor structure, a fin-based transistor structure, or a gate-all-around transistor structure, with a group IV element (e.g., silicon, germanium) or a group III-V element (e.g., gallium arsenic, indium arsenic) serving as its channel material. The BEOL transistors (e.g., the access transistors in the portion 520) may each be implemented as a number of sub-transistors connected in parallel. These BEOL sub-transistors may each be configured as a thin-film transistor structure or back-gate transistor structure, with a semiconductive-behaving oxide material (e.g., indium gallium zinc oxide (IGZO, InZnO, InSnO, SnO₂, MgAlZnO, CuO, SnO, oxides of the Delafossite group Cu—X—O with or without doping, or combinations thereof) serving as its channel material.

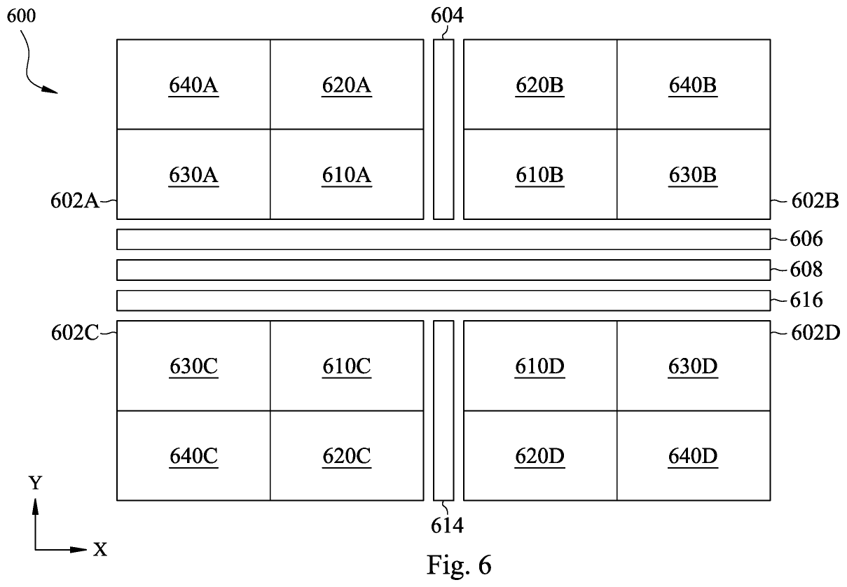

FIG. 6 illustrates a block diagram of a memory device 600, in accordance with various embodiments. As shown, the memory device 600 includes a number of memory arrays 602A, 602B, 602C, and 602D, a number of WL driver circuits 604 and 614, a number of BL driver circuits 606 and 616, and an I/O circuit 608. The memory device 600 may be substantially similar to the memory device 100 shown in FIG. 1, except that the memory device 600 includes more than one memory array and additional corresponding WL driver circuit(s) and BL driver circuit(s).

In some embodiments, two or more of the memory arrays 602A to 602D may operatively share some of these peripheral circuits (e.g., WL driver circuits 604 and 614, BL driver circuits 606 and 616, and I/O circuit 608, etc.). For example, the memory array 602A and 602B may share the same WL driver circuit 604 and the same BL driver circuit 606; the memory array 602C and 602D may share the same WL driver circuit 614 and the same BL driver circuit 616; and the memory arrays 602A to 602D may share the same I/O circuit 608. Further, each of the memory arrays 602A to 602D can each have its memory cells grouped according to one of the arrangements discussed above with respect to FIGS. 3-5. In the illustrative example of FIG. 6, each of the memory arrays 602A to 602D has four evenly divided portions similar to the arrangement 300 (FIG. 3).

For example, the memory array 602A has four portions 610A, 620A, 630A, and 640A grouped according to their respective positions with respect to the corresponding WL driver circuit 604, the BL driver circuit 606, and the I/O circuit 608; the memory array 602B has four portions 610B, 620B, 630B, and 640B grouped according to their respective positions with respect to the corresponding WL driver circuit 604, the BL driver circuit 606, and the I/O circuit 608; the memory array 602C has four portions 610C, 620C, 630C, and 640C grouped according to their respective positions with respect to the corresponding WL driver circuit 614, the BL driver circuit 616, and the I/O circuit 608; and the memory array 602D has four portions 610D, 620D, 630D, and 640D grouped according to their respective positions with respect to the corresponding WL driver circuit 614, the BL driver circuit 616, and the I/O circuit 608.

According to one aspect of the present disclosure, the access transistors (of the memory cells) in the portions 610A, 610B, 610C, and 610D may each have a first threshold voltage; the access transistors (of the memory cells) in the portions 620A, 620B, 620C, and 620D may each have a second threshold voltage; the access transistors (of the memory cells) in the portions 630A, 630B, 630C, and 630D may each have a third threshold voltage; and the access transistors (of the memory cells) in the portions 640A, 640B, 640C, and 640D may each have a fourth threshold voltage. In some embodiments, the fourth threshold voltage is substantially less than the third threshold voltage, which is equal to the second threshold voltage, which is substantially less than the first threshold voltage.

According to another aspect of the present disclosure, the access transistors (of the memory cells) in the portions 610A, 610B, 610C, and 610D may each be formed in a FEOL network (e.g., along the major surface of a corresponding substrate); the access transistors (of the memory cells) in the portions 620A, 620B, 620C, and 620D may each be formed in a BEOL network (e.g., in one or more metallization layers disposed over the major surface of the corresponding substrate); the access transistors (of the memory cells) in the portions 630A, 630B, 630C, and 630D may each be formed in the FEOL network; and the access transistors (of the memory cells) in the portions 640A, 640B, 640C, and 640D may be formed in the BEOL network.

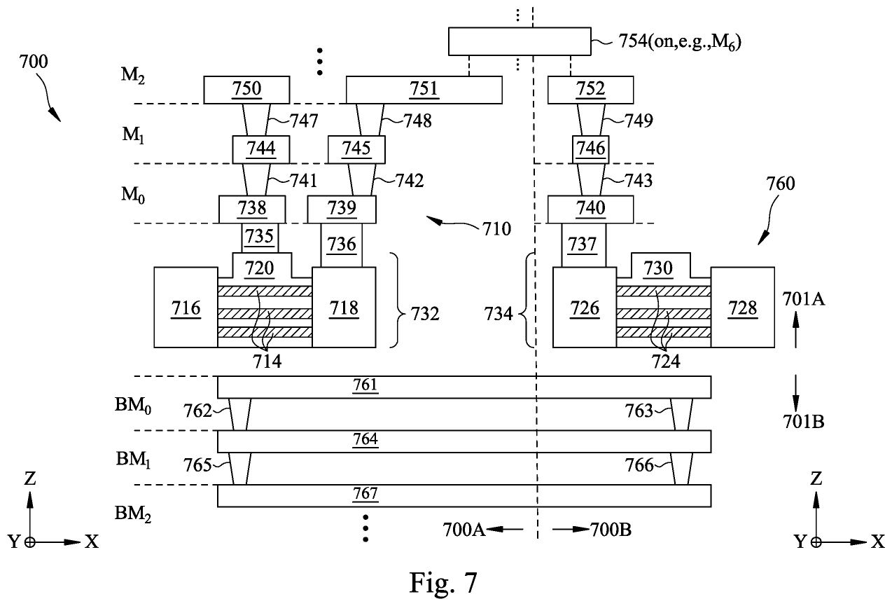

FIG. 7 illustrates a cross-sectional view of an example semiconductor device 700 including a memory cell 710 and a driver or I/O component 760 electrically coupled to each other, in accordance with various embodiments. The memory cell 710 can be a non-limiting implementation of the efuse memory cell 103 (FIGS. 1-2), and the driver or I/O component 760 can be a non-limiting implementation of one of the transistors of the BL driver circuit 106 or the I/O circuit 108 (FIG. 1). Hereinafter, the memory cell 710 and the component 760 are referred to as “efuse memory cell 710” and “peripheral component 760,” respectively.

The efuse memory cell 710 includes a fuse resistor and an access transistor connected to each other in series that are formed on the frontside 701A of a substrate (not explicitly shown in FIG. 7). The cross-sectional view of FIG. 7 is cut along the lengthwise direction of a channel of the access transistor of the efuse memory cell 710 (e.g., the X direction). The access transistor may be implemented as a gate-all-around (GAA) field-effect-transistor (FET) device, in some embodiments. However, it should be understood that the access transistor can be implemented as any of various other types of transistor structures, while remaining within the scope of the present disclosure. FIG. 7 is simplified to illustrate relatively spatial configurations of the above-discussed structures, and thus, it should be understood that one or more features/structures of a completed GAA FET device may not be displayed for clarity.

On the frontside 701A, the semiconductor device 700 includes an active region (sometimes referred to as an oxide diffusion region) having portions being formed as a number of channels, e.g., 714 and 724, and portions being formed as source/drain structures, e.g., 716, 718, 726, and 728. The channels 714 and 724 each include one or more nanostructures (e.g., nanosheets, nanowires) vertically spaced apart from each other. The semiconductor device 700 includes a number of (e.g., metal) gate structures, e.g., 720 and 730, each on which wraps around the nanostructures of a corresponding channel. For example, the gate structure 720 wraps around each of the nanostructures of the channel 714; and the gate structure 730 wraps around each of the nanostructures of the channel 724. Further, each channel is connected to one or more source/drain structures so as to form a transistor (e.g., a GAA FET). For example, the channel 714, gate structure 720 (wrapping around the channel 714), and source/drain structures 716-718 (connected to the channel 714) form a first transistor 732; and the channel 724, gate structure 730 (wrapping around the channel 724), and source/drain structures 726-728 (connected to the channel 724) form a second transistor 734. The first transistor 732 can be an access transistor of the efuse memory cell 710, and the second transistor 734 can be part of the peripheral component 760, in accordance with some embodiments.

Over the transistors on the frontside 701A, a number of middle-end interconnect (e.g., metal) structures can be formed, and each of the middle-end interconnect structures can provide an electrical connection path for a corresponding gate structure or source/drain structure. For example, the semiconductor device 700 includes middle-end interconnect structures 735, 736, and 737. The middle-end interconnect structure 735 is formed as a via structures and in electrical contact with the gate structure 720 (which is sometimes referred to as “VG”), and the middle-end interconnect structures 736 and 737 are in electrical contact with the source/drain structures 718 and 726, respectively (which are sometimes referred to as “MDs”).

Over the middle-end interconnect structures (e.g., VG, MD), the semiconductor device 700 includes a number of frontside metallization layers. Each of the frontside metallization layers includes a number of back-end interconnect structures, metal lines and via structures, embedded in a corresponding dielectric material (e.g., an inter-metal dielectric (IMD)). For example, the semiconductor device 700 includes a plural number of frontside metallization layers disposed on top of one another, M0, M1, M2, and so on. Although three frontside metallization layers are shown, it should be understood that the semiconductor device 700 can include any number of frontside metallization layers while remaining within the scope of the present disclosure.

The frontside metallization layer M0 includes metal lines 738, 739, and 740 (which are sometimes referred to as “M0 tracks”), and via structures 741, 742, and 743 (which are sometimes referred to as “V0”); the frontside metallization layer M1 includes metal lines 744, 745, and 746 (which are sometimes referred to as “M1 tracks”), and via structures 747, 748, and 749 (which are sometimes referred to as “V1”); and the frontside metallization layer M2 includes metal lines 750, 751, and 752 (which are sometimes referred to as “M2 tracks”). As a non-limiting example, the VG 735 can allow the gate structure 720 to be in electrical contact with the M2 track 750 through the M0 track 738, V0 741, M1 track 744, and V1 747; the MD 736 can allow the source/drain structure 718 to be in electrical contact with the M2 track 751 through the M0 track 739, V0 742, M1 track 745, and V1 748; and the MD 737 can allow the source/drain structure 726 to be in electrical contact with the M2 track 752 through the M0 track 739, V0 742, M1 track 745, and V1 748.

In the example of FIG. 7, the first transistor 732 can operatively serve as the access transistor of the efuse memory cell 710 (e.g., an implementation of the access transistor 204 of FIG. 2), the M2 track 751 can operatively serve as the fuse resistor of the efuse memory cell 710 (e.g., an implementation of the fuse resistor 202 of FIG. 2), and the second transistor 734 can operatively serve as a switch/selection transistor coupled to the efuse memory cell 710.

Further, the M2 track 751 has a first end in electrical connection with the first transistor 732 through one of its source/drain structures 718, and a second end in electrical connection with a metal line 754 (e.g., an operative implementation of the BL of FIG. 2). The other source/drain structure 716 of the first transistor 732 may be coupled to ground through one or more other metal lines (not shown). The metal line 754 may be disposed in one of the frontside metallization layers higher than M2 such as, for example, M6, with at least M3, M4, and M5 interposed therebetween. In response to the first transistor 732 being activated through a voltage signal applied on its word line (WL), which may be implemented as at least one of the M0 track 738, M1 track 744, or M2 track 750, the second transistor 734 can be activated to couple a programming voltage or reading voltage to the M2 track 751 (the fuse resistor 202) through the metal line 754. Referring again to the block diagram of FIG. 1, a plural number of such efuse memory cells (e.g., 710) can form the memory array (e.g., 102) of a memory device, while a plural number of such switch/selection transistors (e.g., 734) can form an I/O circuit (e.g., 108) or BL driver circuit (e.g., 106) of the corresponding memory device.

In some embodiments of the present disclosure, the memory array may be formed in a first region of the substrate (e.g., 700A), while the I/O and BL driver circuit may be formed in a second region of the substrate (e.g., 700B). The second region 700B is laterally next to the first region 700A, just like the arrangements 300, 400, and 500 shown in FIGS. 3, 4, and 5, respectively. For example, the first region 700A may correspond to at least one of the portions 310 to 340 in FIG. 3, at least one of the portions 410 to 440 in FIG. 4, or at least one of the portions 510 to 520 in FIG. 5, while the second region 700B may correspond to 106/108 of FIGS. 3-5. In some embodiments, the first region 700A and the second region 700B can be arranged with respect to each other along a lengthwise direction of the gate structure 720/730 (e.g., the Y-direction). Alternatively, the first region 700A and the second region 700B may be arranged with respect to each other along the lengthwise direction of the channel 714/724 (e.g., the X-direction). The second region 700B (sometimes referred to as “peripheral region 700B”) can be configured as a closed-end or an open-end ring surrounding the first region 700A (sometimes referred to as “memory region 700A”).

On the backside 701B, the semiconductor device 700 includes a number of backside metallization layers. Each of the backside metallization layers includes a number of back-end interconnect structures, metal lines and via structures, embedded in a corresponding dielectric material (e.g., an inter-metal dielectric (IMD)). For example, the semiconductor device 700 includes a plural number of backside metallization layers disposed on top of one another, BM0, BM1, BM2, and so on. Although three backside metallization layers are shown, it should be understood that the semiconductor device 700 can include any number of backside metallization layers while remaining within the scope of the present disclosure.

The backside metallization layer BM0 includes metal line 761 (which is sometimes referred to as “BM0 track”), and via structures 762 and 763 (which are sometimes referred to as “BV0s”); the backside metallization layer BM1 includes metal line 764 (which is sometimes referred to as “BM1 track”), and via structures 765 and 766 (which are sometimes referred to as “BV1s”); and the backside metallization layer BM2 includes metal line 767 (which is sometimes referred to as “BM2 track”). In some embodiments, one or more of these backside metal lines may extend across at least one of the memory region 700A or peripheral region 700B, and can operatively carry a respective supply voltage to power the transistors 732 and 734 formed on the frontside. For example, one of the backside metal lines is configured to provide a first supply voltage (e.g., VSS) to the first transistor 732, and another one of the backside metal lines is configured to provide a second supply voltage (e.g., VDD) to the second transistor 734. Such backside metal lines may sometimes be referred to as backside (or super) power rails.

The semiconductor device 700 of FIG. 7 illustrates one of various implementations of the memory array 102 (e.g., the arrangement 300 of FIG. 3, the arrangement 400 of FIG. 4, the arrangement 500 of FIG. 5), where the access transistors of all the memory cells are formed in a FEOL network. Further, different portions of the memory array 102 may have respective electrical characteristics. Using the arrangement 300 of FIG. 3 as a representative example, the first transistors 732 in the portion 310 may have a first threshold voltage, the first transistors 732 in the portions 320-330 may have a second threshold voltage, and the first transistors 732 in the portion 340 may have a third threshold voltage, where the first threshold voltage is higher than the second threshold voltage and the second threshold voltage is higher than the third threshold voltage. Accordingly, the gate structures 720 in these different portions 310-340 may be configured with respective physical parameters. Additionally or alternatively, the channel 714 in these different portions 310-340 may be configured with respective physical parameters.

For example, the gate structures 720 in the portion 310 may each have a first thickness of its gate dielectric layer, the gate structures 720 in the portions 320-330 may each have a second thickness of its gate dielectric layer, and gate structures 720 in the portion 340 may each have a third thickness of its gate dielectric layer. The first thickness may be thicker than the second thickness, and the second thickness may be thicker than the third thickness. Thus, the threshold voltage associated with the portion 310 can be greater than the threshold voltage associated with the portions 320-330, and the threshold voltage associated with the portions 320-330 can be greater than the threshold voltage associated with the portion 340. In another example, the gate structures 720 in the portion 310 may each have a first dielectric constant of its gate dielectric layer, the gate structures 720 in the portions 320-330 may each have a second dielectric constant of its gate dielectric layer, and gate structures 720 in the portion 340 may each have a third dielectric constant of its gate dielectric layer. The first dielectric constant may be lower than the second dielectric constant, and the second dielectric constant may be lower than the third dielectric constant. Thus, the threshold voltage associated with the portion 310 can be greater than the threshold voltage associated with the portions 320-330, and the threshold voltage associated with the portions 320-330 can be greater than the threshold voltage associated with the portion 340. In yet another example, the gate structures 720 in the portion 310 may each have a first combination of work function layers (leading to a first flat band voltage), the gate structures 720 in the portions 320-330 may each have a second combination of work function layers (leading to a second flat band voltage), and gate structures 720 in the portion 340 may each have a third combination of work function layers (leading to a third flat band voltage). The first flat band voltage may be higher than the second flat band voltage, and the second flat band voltage may be higher than the third flat band voltage. Thus, the threshold voltage associated with the portion 310 can be greater than the threshold voltage associated with the portions 320-330, and the threshold voltage associated with the portions 320-330 can be greater than the threshold voltage associated with the portion 340. In yet another example, the channel 714 in the portion 310 may have a first doping concentration, the channel 714 in the portions 320-330 may have a second doping concentration, and the channel 714 in the portion 340 may have a third doping concentration. The first doping concentration may be higher than the second doping concentration, and the second doping concentration may be higher than the third doping concentration. Thus, the threshold voltage associated with the portion 310 can be greater than the threshold voltage associated with the portions 320-330, and the threshold voltage associated with the portions 320-330 can be greater than the threshold voltage associated with the portion 340.

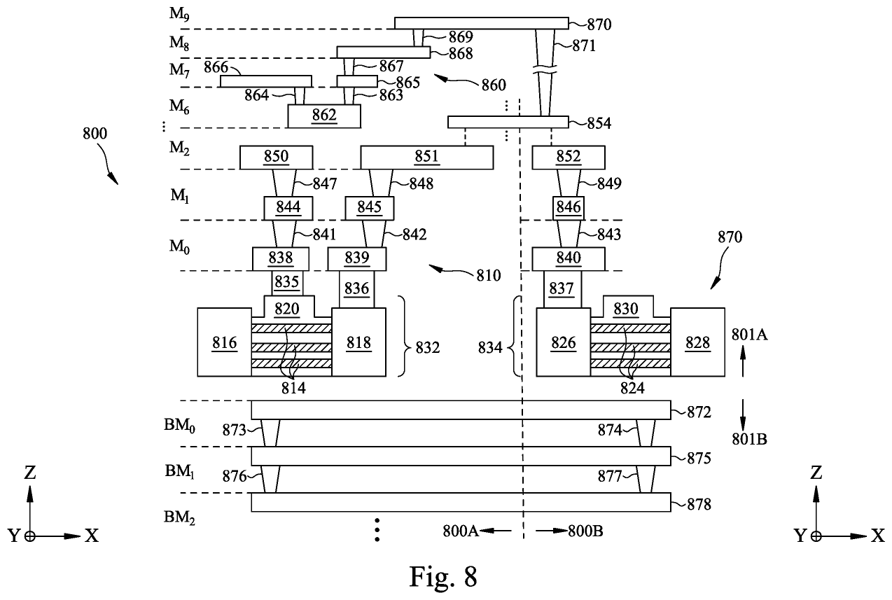

FIG. 8 illustrates a cross-sectional view of another example semiconductor device 800 including a first memory cell 810 and a second memory cell 860, each of which is electrically coupled to a driver or I/O component 870, in accordance with various embodiments. The memory cells 810 and 860 can each be a non-limiting implementation of the efuse memory cell 103 (FIGS. 1-2), and the driver or I/O component 870 can be a non-limiting implementation of one of the transistors of the BL driver circuit 106 or the I/O circuit 108 (FIG. 1). Hereinafter, the memory cell 810, the memory cell 860, and the component 870 are referred to as “efuse memory cell 810,” “efuse memory cell 860,” and “peripheral component 870,” respectively.

It should be appreciated that the semiconductor device 800 is similar to the semiconductor device 700 (FIG. 7), except that the semiconductor device 800 includes at least two efuse memory cells (e.g., 810 and 860) with their respective access transistors formed in a FEOL network (sometimes referred to as a “FEOL access transistor”) and a BEOL network (sometimes referred to as a “BEOL access transistor”), respectively. By forming the access transistors of some of the efuse memory cells in the BEOL network, even if those efuse memory cells are disposed farther from a corresponding peripheral component (e.g., the memory cells in the portion 320, 340, 420, 440, or 520), respective distances extending from the same peripheral component (or BL) to the access transistors may be brought closer or even the same. As such, an IR drop that the memory cells, disposed farther with respect to the BL driver circuit or I/O circuit, would have suffered can be significantly mitigated.

The efuse memory cell 810 includes a fuse resistor and an access transistor connected to each other in series that are formed on the frontside 801A of a substrate (not explicitly shown in FIG. 8). The cross-sectional view of FIG. 8 is cut along the lengthwise direction of a channel of the access transistor of the efuse memory cell 810 (e.g., the X direction). The access transistor may be implemented as a gate-all-around (GAA) field-effect-transistor (FET) device, in some embodiments. However, it should be understood that the access transistor can be implemented as any of various other types of transistor structures, while remaining within the scope of the present disclosure. FIG. 8 is simplified to illustrate relatively spatial configurations of the above-discussed structures, and thus, it should be understood that one or more features/structures of a completed GAA FET device may not be displayed for clarity.

On the frontside 801A, the semiconductor device 800 includes an active region (sometimes referred to as an oxide diffusion region) having portions being formed as a number of channels, e.g., 814 and 824, and portions being formed as source/drain structures, e.g., 816, 818, 826, and 828. The channels 814 and 824 each include one or more nanostructures (e.g., nanosheets, nanowires) vertically spaced apart from each other. The semiconductor device 800 includes a number of (e.g., metal) gate structures, e.g., 820 and 830, each on which wraps around the nanostructures of a corresponding channel. For example, the gate structure 820 wraps around each of the nanostructures of the channel 814; and the gate structure 830 wraps around each of the nanostructures of the channel 824. Further, each channel is connected to one or more source/drain structures so as to form a transistor (e.g., a GAA FET). For example, the channel 814, gate structure 820 (wrapping around the channel 814), and source/drain structures 816-818 (connected to the channel 814) form a first transistor 832; and the channel 824, gate structure 830 (wrapping around the channel 824), and source/drain structures 826-828 (connected to the channel 824) form a second transistor 834. The first transistor 832 can be an access transistor of the efuse memory cell 810, and the second transistor 834 can be part of the peripheral component 870, in accordance with some embodiments.

Over the transistors on the frontside 801A, a number of middle-end interconnect (e.g., metal) structures can be formed, and each of the middle-end interconnect structures can provide an electrical connection path for a corresponding gate structure or source/drain structure. For example, the semiconductor device 800 includes middle-end interconnect structures 835, 836, and 837. The middle-end interconnect structure 835 is formed as a via structures and in electrical contact with the gate structure 820 (which is sometimes referred to as “VG”), and the middle-end interconnect structures 836 and 837 are in electrical contact with the source/drain structures 818 and 826, respectively (which are sometimes referred to as “MDs”).

Over the middle-end interconnect structures (e.g., VG, MD), the semiconductor device 800 includes a number of frontside metallization layers. Each of the frontside metallization layers includes a number of back-end interconnect structures, metal lines and via structures, embedded in a corresponding dielectric material (e.g., an inter-metal dielectric (IMD)). For example, the semiconductor device 800 includes a plural number of frontside metallization layers disposed on top of one another, M0, M1, M2 . . . . M6, M7, M8, M9, and so on. Although seven frontside metallization layers are shown, it should be understood that the semiconductor device 800 can include any number of frontside metallization layers while remaining within the scope of the present disclosure.

The frontside metallization layer M0 includes metal lines 838, 839, and 840 (which are sometimes referred to as “M0 tracks”), and via structures 841, 842, and 843 (which are sometimes referred to as “V0”); the frontside metallization layer M1 includes metal lines 844, 845, and 846 (which are sometimes referred to as “M1 tracks”), and via structures 847, 848, and 849 (which are sometimes referred to as “V1”); and the frontside metallization layer M2 includes metal lines 850, 851, and 852 (which are sometimes referred to as “M2 tracks”). As a non-limiting example, the VG 835 can allow the gate structure 820 to be in electrical contact with the M2 track 850 through the M0 track 838, V0 841, M1 track 844, and V1 847; the MD 836 can allow the source/drain structure 818 to be in electrical contact with the M2 track 851 through the M0 track 839, V0 842, M1 track 845, and V1 848; and the MD 837 can allow the source/drain structure 826 to be in electrical contact with the M2 track 852 through the M0 track 839, V0 842, M1 track 845, and V1 848.

In the example of FIG. 8, the first transistor 832 can operatively serve as the access transistor of the efuse memory cell 810 (e.g., an implementation of the access transistor 204 of FIG. 2), the M2 track 851 can operatively serve as the fuse resistor of the efuse memory cell 810 (e.g., an implementation of the fuse resistor 202 of FIG. 2), and the second transistor 834 can operatively serve as a switch/selection transistor coupled to the efuse memory cell 810.

Further, the M2 track 851 has a first end in electrical connection with the first transistor 832 through one of its source/drain structures 818, and a second end in electrical connection with a metal line 854 (e.g., an operative implementation of the BL of FIG. 2). The other source/drain structure 816 of the first transistor 832 may be coupled to ground through one or more other metal lines (not shown). The metal line 854 may be embodied as a metal line in one of the frontside metallization layers higher than M2 such as, for example, M6, with at least M3, M4, and M5 interposed therebetween. In response to the first transistor 832 being activated through a voltage signal applied on its word line (WL), which may be one of the M0 track 838, M1 track 844, or M2 track 850, the second transistor 834 can be activated to couple a programming voltage or reading voltage to the M2 track 851 (the fuse resistor 202) through the metal line 854.

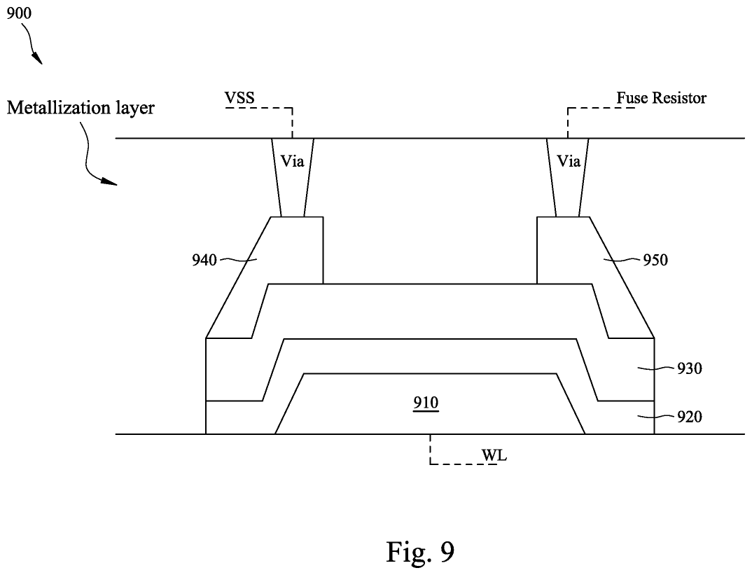

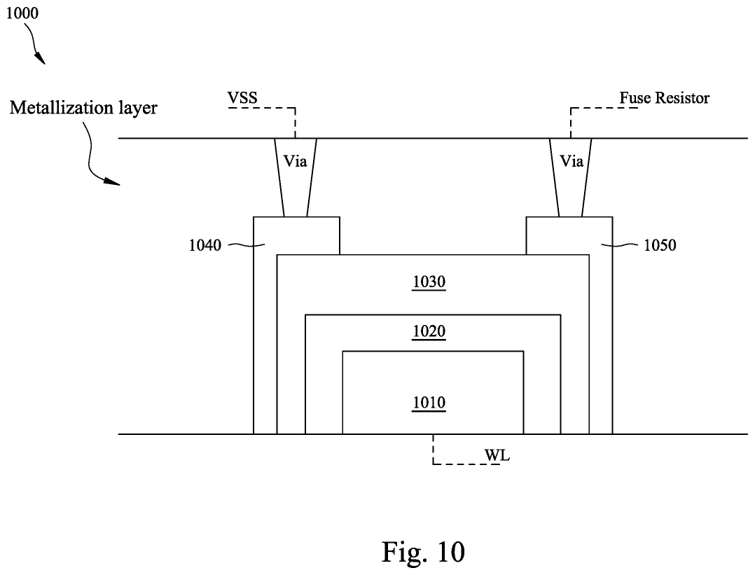

The semiconductor device 800 further includes a third transistor 862 formed in one of the metallization layers, e.g., the frontside metallization layer M6. The third transistor 862 may be implemented as a two-dimensional or three-dimensional back-gate transistor structure, which will be discussed below with respect to FIG. 9-10. The frontside metallization layer M6 includes via structures 863 and 864 (which are sometimes referred to as “V6”), which may be connected to source/drain structures of the third transistor 862, respectively. The frontside metallization layer M7 includes metal lines 865 and 866 (which are sometimes referred to as “M7 tracks”), and via structure 867 (which is sometimes referred to as “V7”); the frontside metallization layer M8 includes metal line 868 (which is sometimes referred to as “M8 track”), and via structure 869 (which is sometimes referred to as “V8”); and the frontside metallization layer M9 includes metal line 870 (which is sometimes referred to as “M9 track”).

In the example of FIG. 8, the third transistor 862 can operatively serve as the access transistor of the efuse memory cell 860 (e.g., an implementation of the access transistor 204 of FIG. 2), and the M8 track 868 can operatively serve as the fuse resistor of the efuse memory cell 860 (e.g., an implementation of the fuse resistor 202 of FIG. 2). Further, the M8 track 868 has a first end in electrical connection with the third transistor 862 through one of its source/drain structures, and a second end in electrical connection with the metal line 854 through the V8 869, M9 track 870, and one or more via structures 871. The other source/drain structure of the third transistor 862 may be coupled to ground through one or more other metal lines, e.g., 866. Similar to the operation of the efuse memory cell 810, in response to the third transistor 862 being activated through a voltage signal applied on its WL (not shown), the second transistor 834 can be activated to couple a programming voltage or reading voltage to the M8 track 868 (the fuse resistor 202) through the metal line 854.

Referring again to the block diagram of FIG. 1, a plural number of such efuse memory cells (e.g., 810 and 860) can form the memory array (e.g., 102) of a memory device, while a plural number of such switch/selection transistors (e.g., 834) can form an I/O circuit (e.g., 108) or BL driver circuit (e.g., 106) of the corresponding memory device. In some embodiments of the present disclosure, the memory array may be formed in a first region of the substrate (e.g., 800A), while the I/O and BL driver circuit may be formed in a second region of the substrate (e.g., 800B). The second region 800B is laterally next to the first region 800A, just like the arrangements 300, 400, and 500 shown in FIGS. 3, 4, and 5, respectively. For example, the first region 800A may correspond to at least one of the portions 310 to 340 in FIG. 3, at least one of the portions 410 to 440 in FIG. 4, or at least one of the portions 510 to 520 in FIG. 5, while the second region 800B may correspond to 106/108 of FIGS. 3-5. In some embodiments, the first region 800A and the second region 800B can be arranged with respect to each other along a lengthwise direction of the gate structure 820/830 (e.g., the Y-direction). Alternatively, the first region 800A and the second region 800B may be arranged with respect to each other along the lengthwise direction of the channel 814/824 (e.g., the X-direction). The second region 800B (sometimes referred to as “peripheral region 800B”) can be configured as a closed-end or an open-end ring surrounding the first region 800A (sometimes referred to as “memory region 800A”).

Further, the efuse memory cells 810 (having the FEOL access transistors) may correspond to the near portions 310 and 330, while the efuse memory cells 860 (having the BEOL access transistors) may correspond to the far portions 320 and 340; the efuse memory cells 810 (having the FEOL access transistors) may correspond to the near portions 410 and 430, while the efuse memory cells 860 (having the BEOL access transistors) may correspond to the far portions 420 and 440; and the efuse memory cells 810 (having the FEOL access transistors) may correspond to the near portion 510, while the efuse memory cells 860 (having the BEOL access transistors) may correspond to the far portion 520. Stated another way, the far and near portions of the memory array 102 may have respectively different physical characteristics.

As such, the far portion 320 that was originally disposed far away from the I/O circuit 108 and BL driver circuit 106 can be moved to the top of the near portion 310. Consequently, the respective physical distances extending from the I/O circuit 108 (and BL driver circuit 106) to the access transistors in the far portion 320 and to the access transistors in the near portion 310 can be close to each other, which can equivalently balance the IR drops between the far portion and the near portion. Similarly, the far portion 340 can be moved to the top of the near portion 330 to have a similar IR drop; the far portion 420 can be moved to the top of the near portion 410 to have a similar IR drop; the far portion 440 can be moved to the top of the near portion 430 to have a similar IR drop; and the far portion 520 can be moved to the top of the near portion 510 to have a similar IR drop.

On the backside 801B, the semiconductor device 800 includes a number of backside metallization layers. Each of the backside metallization layers includes a number of back-end interconnect structures, metal lines and via structures, embedded in a corresponding dielectric material (e.g., an inter-metal dielectric (IMD)). For example, the semiconductor device 800 includes a plural number of backside metallization layers disposed on top of one another, BM0, BM1, BM2, and so on. Although three backside metallization layers are shown, it should be understood that the semiconductor device 800 can include any number of backside metallization layers while remaining within the scope of the present disclosure.

The backside metallization layer BM0 includes metal line 872 (which is sometimes referred to as “BM0 track”), and via structures 873 and 874 (which are sometimes referred to as “BV0s”); the backside metallization layer BM1 includes metal line 875 (which is sometimes referred to as “BM1 track”), and via structures 876 and 877 (which are sometimes referred to as “BV1s”); and the backside metallization layer BM2 includes metal line 878 (which is sometimes referred to as “BM2 track”). In some embodiments, one or more of these backside metal lines may extend across at least one of the memory region 800A or peripheral region 800B, and can operatively carry a respective supply voltage to power the transistors 832, 834, and 862 formed on the frontside. For example, one of the backside metal lines is configured to provide a first supply voltage (e.g., VSS) to the first transistor 832 and third transistor 862, and another one of the backside metal lines is configured to provide a second supply voltage (e.g., VDD) to the second transistor 834. Such backside metal lines may sometimes be referred to as backside (or super) power rails.

FIGS. 9 and 10 illustrate respective cross-sectional views of implementations 900 and 1000 of the third transistor 862, in accordance with various embodiments. Hereinafter, the implementations 900 and 1000 are referred to as “transistor 900” and “transistor 1000,” respectively. As mentioned above in FIG. 8, the third transistor 862 (e.g., 900, 1000) is formed in one of the metallization layers (i.e., in/through a BEOL network), which may include a conductive oxide functioning as its channel material. In general, such a conductive oxide can be formed (e.g., deposited) in a relatively low temperature, which is compatible with the general process temperature in a BEOL network.

In FIG. 9, the transistor 900 has each of its components embedded in one or more dielectric layers of a corresponding metallization layer. In some embodiments, the transistor 900 is formed as a two-dimensional back-gate transistor consisting of a bottom gate 910, a gate dielectric 920 disposed over the bottom gate 910, a channel structure 930 disposed over the gate dielectric 920, and a pair of source/drain structures 940 and 950 disposed over the channel structure 930. The term “two-dimensional back-gate transistor” may refer to a transistor having its gate formed as a relatively planar structure and its channel structure contacting a top surface of the gate. The bottom gate 910, gate dielectric 920, channel structure 930, and source/drain structures 940 and 950 are all disposed in one of the metallization layers over a substrate. Further, the bottom gate 910, and the source/drain structures 940 and 950 may each be formed as a metal line embedded in a ILD/IMD of the metallization layer. In some embodiments, the bottom gate 910 may be connected to a WL disposed below the metallization layer where the bottom gate 910, gate dielectric 920, channel structure 930, and source/drain structures 940 and 950 are formed, and the source/drain structures 940 and 950 may be in electrical connection to VSS and a corresponding fuse resistor through respective via structures, e.g., 864 and 863 in FIG. 8.

To compatibly fabricate the transistor 900 in the BEOL network, the channel structure 930 may include one or more n-type or p-type semiconductive-behaving oxide materials or two-dimensional (2D) materials. For example, the channel structure 930 may include one or more n-type semiconductive-behaving oxide materials such as, for example, IGZO, InZnO, InSnO, SnO₂, MgAlZnO, etc. In some other embodiments, the channel structure 930 may be formed of one or more n-type 2D materials such as, for example, transition metal dichalcogenide (TMD) material, graphene, etc. The 2D material generally refers to crystalline solids consisting of a single layer of atoms. The single layer of atoms can be derived from single elements or multiple elements. The 2D material may include a compound of transition metal atoms (Mo, W, Ti, or the like) and chalcogen atoms (S, Se, Te, or the like) such as, for example, WS2, WSe2, WTe2, MoS₂, MoSe₂, MoTe₂, HfS₂, ZrS₂, and TiS₂, GaSe, InSe, phosphorene, and other similar materials. In another example, the channel structure 930 may include one or more p-type semiconductive-behaving oxide materials such as, for example, CuO, SnO, oxides of the Delafossite group Cu—X—O with or without doping, etc. In some other embodiments, the channel structure 930 may be formed of one or more p-type 2D materials such as, for example, transition metal dichalcogenide (TMD) material, graphene, etc.

In FIG. 10, the transistor 1000 has each of its components embedded in one or more dielectric layers of a corresponding metallization layer. In some embodiments, the transistor 1000 is formed as three-dimensional back-gate transistor. The term “three-dimensional back-gate transistor” may refer to a transistor having its gate formed as a relatively protruding structure and its channel structure contacting multiple surfaces of the gate. For example, the transistor 1000 consists of a bottom gate 1010, a gate dielectric 1020 disposed over the bottom gate 1010, a channel structure 1030 disposed over the gate dielectric 1020, and a pair of source/drain structures 1040 and 1050 disposed over the channel structure 1030. The bottom gate 1010, gate dielectric 1020, channel structure 1030, and source/drain structures 1040 and 1050 are all disposed in in one of the metallization layers over a substrate. Further, the bottom gate 1010, and the source/drain structures 1040 and 1050 may each be formed as a metal line embedded in a ILD/IMD of the metallization layer. The gate dielectric 1020 and the channel structure 1030 may be sequentially conformally formed over the bottom gate 1010. As such, the bottom gate 1010 can have at least three surfaces, e.g., its top surface and sidewalls, operatively (e.g., electrically) coupled to the channel structure 1030. In some embodiments, the bottom gate 1010 may be connected to a WL disposed below the metallization layer where the bottom gate 1010, gate dielectric 1020, channel structure 1030, and source/drain structures 1040 and 1050 are formed, and the source/drain structures 1040 and 1050 may be in electrical connection to VSS and a corresponding fuse resistor through respective via structures, e.g., 864 and 863 in FIG. 8.

Similarly, the channel structure 1030 may include one or more n-type or p-type semiconductive-behaving oxide materials or two-dimensional (2D) materials. For example, the channel structure 1030 may include one or more n-type semiconductive-behaving oxide materials such as, for example, IGZO, InZnO, InSnO, SnO₂, MgAlZnO, etc. In some other embodiments, the channel structure 1030 may be formed of one or more n-type 2D materials such as, for example, transition metal dichalcogenide (TMD) material, graphene, etc. The 2D material generally refers to crystalline solids consisting of a single layer of atoms. The single layer of atoms can be derived from single elements or multiple elements. The 2D material may include a compound of transition metal atoms (Mo, W, Ti, or the like) and chalcogen atoms (S, Se, Te, or the like) such as, for example, WS2, WSe2, WTe2, MoS₂, MoSe₂, MoTe₂, HfS₂, ZrS₂, and TiS₂, GaSe, InSe, phosphorene, and other similar materials. In another example, the channel structure 1030 may include one or more p-type semiconductive-behaving oxide materials such as, for example, CuO, SnO, oxides of the Delafossite group Cu—X—O with or without doping, etc. In some other embodiments, the channel structure 1030 may be formed of one or more p-type 2D materials such as, for example, transition metal dichalcogenide (TMD) material, graphene, etc.

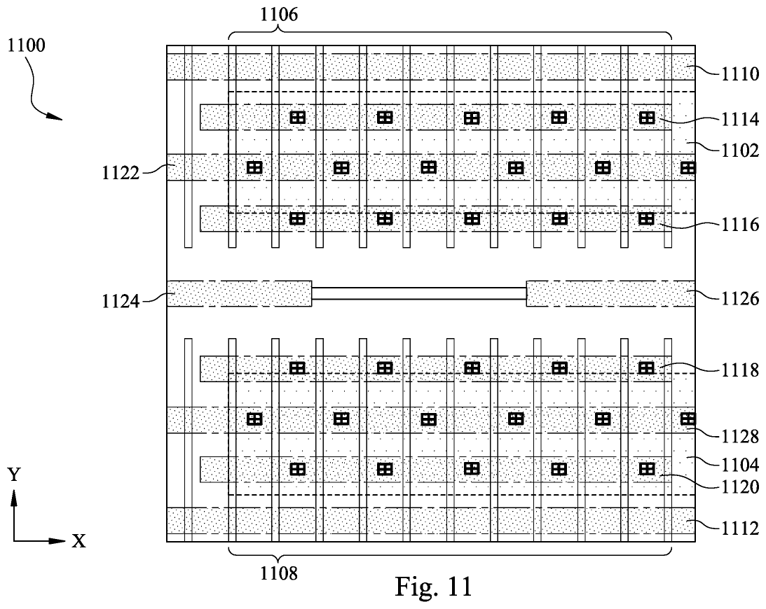

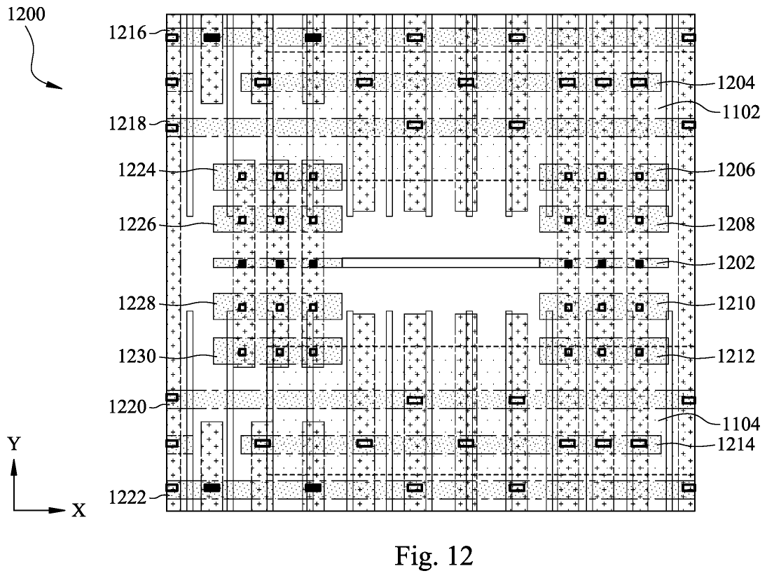

FIGS. 11 and 12 collectively illustrate an example layout configured to form the disclosed efuse memory cell (e.g., 710 of FIG. 7, 810 of FIG. 8), in accordance with various embodiments. Thus, the following discussion of the layout may sometimes be referred to the components shown in FIGS. 7-8. In brief overview, FIG. 11 corresponds to a first layer 1100 of the layout (hereinafter “layout 1100”), and FIG. 12 corresponds to a second layer 1200 of the layout (hereinafter “layout 1200”). The efuse memory cell, as disclosed herein, is formed of an access transistor and a fuse resistor, in which the access transistor is connected to the fuse resistor in series. Further, the access transistor may be formed in a FEOL network and the fuse resistor may be formed in a BEOL network. For example, the access transistor can be constructed by a number (e.g., about 100) of sub-transistors formed along the major surface of a substrate, in which the sub-transistors are coupled to one another in parallel; and the fuse resistor can be constructed by at least a frontside metal line disposed over those sub-transistors.

Referring first to FIG. 11, the layout 1100 includes patterns 1102 and 1104 that are each configured to form an active region (hereinafter “active region 1102,” and “active region 1104,” respectively); and patterns 1106 and 1108 that are each configured to form a gate structure (hereinafter “gate structure 1106” and “gate structure 1108,” respectively). However, it should be understood that the layout 1100 can include any number of the active regions and gate structures, while remaining within the scope of present disclosure.

The active regions 1102 to 1104 may extend along a first lateral direction (e.g., X-direction), while the gate structures 1106 and 1108 may extend along a second, different lateral direction (e.g., Y-direction). The gate structures 1106 and the gate structures 1108 may be separated from each other along the Y-direction. Further, the gate structures 1106 can each traverse the active region 1102, and the gate structures 1108 can each traverse the active region 1104. In various embodiments, each of the active regions 1102 to 1104 is formed of a stack structure protruding from the frontside surface of a substrate. The stack includes a number of semiconductor nanostructures (e.g., nanosheets) extending along the X-direction and vertically separated from each other. Portions of the semiconductor structures in the stack that are overlaid by the gate structure remain, while other portions are replaced with a number of epitaxial structures. The remaining portions of the semiconductor structures can be configured as the channel of a corresponding transistor (or sub-transistor), the epitaxial structures coupled to both sides (or ends) of the remaining portions of the semiconductor structures can be configured as source/drain structures (or terminals) of the transistor (or sub-transistor), and a portion of the gate structure that overlays (e.g., straddles) the remaining portions of the semiconductor structures can be configured as a gate structures (or terminal) of the transistor (or sub-transistor).

For example in FIG. 11, the portion of the active region 1102 that is overlaid by each of the gate structure 1106 may include a number of nanostructures vertically separated from each other, which can function as the channel of a sub-transistor. The portions of the active region 1102 that are disposed on opposite sides of each of the gate structure portion 1106 are replaced with epitaxial structures. Such epitaxial structures can function as source/drain structures of the sub-transistor. The gate structures 1106 can each function as a gate terminal of sub-transistor. Thus, it should be appreciated that the layout 1100 can be used to fabricate a certain number of such sub-transistors. In some embodiments, such sub-transistors, formed based on the patterns 1102-1104 and 1106-1108, can be electrically coupled to each other in parallel to collectively function as the access transistor of an efuse memory cell (e.g., 710 of FIG. 7, 810 of FIG. 8).

The layout 1100 further includes patterns 1110, 1112, 1114, 1116, 1118, 1120, 1122, 1124, 1126, and 1128 that are each configured to form a metal line (hereinafter “metal line 1110,” “metal line 1112,” “metal line 1114,” “metal line 1116,” metal line 1118,” “metal line 1120,” “metal line 1122,” “metal line 1124,” “metal line 1126,” and “metal line 1128,” respectively). The metal lines 1110 to 1128 may extend along the first lateral direction (e.g., X-direction). The metal lines 1110 to 1128 may each be formed as a metal line disposed in an M0 metallization layer (FIGS. 7-8), e.g., an M0 track. In some embodiments, the metal lines 1110 and 1112 may each operatively serve as an implementation of a WL of the efuse memory cell, sometimes referred to as “WL metal” (through connecting to a gate structure, e.g., 720 or 820, of the access transistor); the metal lines 1122 to 1128 may each be operatively to conduct VSS, sometimes referred to as “VSS metal” (through connecting to one of the source/drain structures, e.g., 716 or 816, of the access transistor); and the metal lines 1114 to 1120 may each be operatively to connect to one end of a corresponding fuse resistor, sometimes referred to as “Vdrain metal” (through connecting to the other of the source/drain structures, e.g., 718 or 818, of the access transistor).

Referring next to FIG. 12, the layout 1200 includes patterns 1202, 1204, 1206, 1208, 1210, 1212, 1214, 1216, 1218, 1220, 1222, 1224, 1226, 1228, and 1230 that are each configured to form a metal line (hereinafter “metal line 1202,” “metal line 1204,” “metal line 1206,” metal line 1208,” “metal line 1210,” “metal line 1212,” “metal line 1214,” “metal line 1216,” “metal line 1218,” “metal line 1220,” “metal line 1222,” “metal line 1224,” “metal line 1226,” “metal line 1228,” and “metal line 1230,” respectively). The metal lines 1202 to 1230 may extend along the first lateral direction (e.g., X-direction). The metal lines 1202 to 1230 may each be formed as a metal line disposed in an M2 metallization layer (FIGS. 7-8), e.g., an M2 track. In some embodiments, the metal line 1202 may operatively serve as the fuse resistor (e.g., 751 or 851); the metal lines 1204 to 1214 may each operatively serve as the Vdrain metal (i.e., connecting the fuse resistor to the other of the source/drain structures, e.g., 718 or 818, of the access transistor); the metal lines 1216 to 1222 may each operatively serve as the VSS metal (i.e., connecting one of the source/drain structures, e.g., 716 or 816, of the access transistor to VSS); and the metal lines 1224 to 1230 may each be operatively to conduct a programming/reading voltage to the other end of the fuse resistor, sometimes referred to as “VDDQI metal” (through connecting to a peripheral component, e.g., 760 or 870).

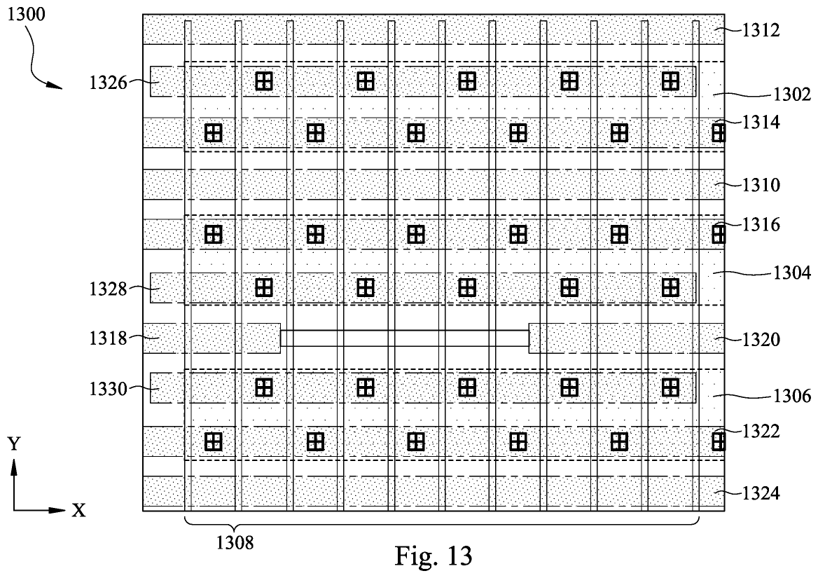

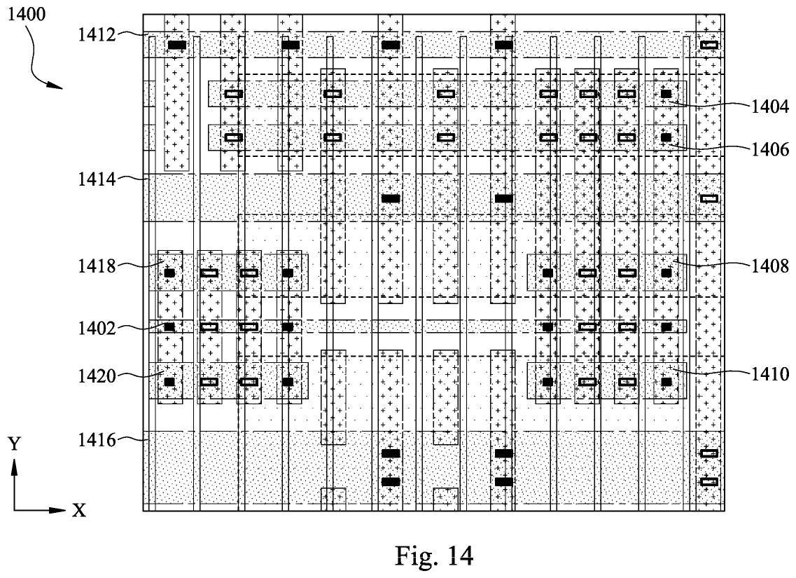

FIGS. 13 and 14 collectively illustrate another example layout configured to form the disclosed efuse memory cell (e.g., 710 of FIG. 7, 810 of FIG. 8), in accordance with various embodiments. Thus, the following discussion of the layout may sometimes be referred to the components shown in FIGS. 7-8. In brief overview, FIG. 13 corresponds to a first layer 1300 of the layout (hereinafter “layout 1300”), and FIG. 14 corresponds to a second layer 1400 of the layout (hereinafter “layout 1400”). The efuse memory cell, as disclosed herein, is formed of an access transistor and a fuse resistor, in which the access transistor is connected to the fuse resistor in series. Further, the access transistor may be formed in a FEOL network and the fuse resistor may be formed in a BEOL network. For example, the access transistor can be constructed by a number (e.g., about 100) of sub-transistors formed along the major surface of a substrate, in which the sub-transistors are coupled to one another in parallel; and the fuse resistor can be constructed by at least a frontside metal line disposed over those sub-transistors.

Referring first to FIG. 13, the layout 1300 includes patterns 1302, 1304, and 1306 that are each configured to form an active region (hereinafter “active region 1302,” active region 1304,” and “active region 1306,” respectively); and patterns 1308 that are each configured to form a gate structure (hereinafter “gate structure 1308”). The layout 1300 is similar to the layout 1100 (FIG. 11) except that the layout 1300 includes three active regions and continuous gate structures each traversing the three active regions. This allows the layout 1300 to have a shorter height in the Y-direction (in turn, a smaller area), when compared to the layout 1100. However, it should be understood that the layout 1300 can include any number of the active regions and gate structures, while remaining within the scope of present disclosure.

The active regions 1302 to 1306 may extend along a first lateral direction (e.g., X-direction), while the gate structures 1308 may extend along a second, different lateral direction (e.g., Y-direction). Further, the gate structures 1308 can each traverse the active regions 1302 to 1306. In various embodiments, each of the active regions 1302 to 1306 is formed of a stack structure protruding from the frontside surface of a substrate. The stack includes a number of semiconductor nanostructures (e.g., nanosheets) extending along the X-direction and vertically separated from each other. Portions of the semiconductor structures in the stack that are overlaid by the gate structure remain, while other portions are replaced with a number of epitaxial structures. The remaining portions of the semiconductor structures can be configured as the channel of a corresponding transistor (or sub-transistor), the epitaxial structures coupled to both sides (or ends) of the remaining portions of the semiconductor structures can be configured as source/drain structures (or terminals) of the transistor (or sub-transistor), and a portion of the gate structure that overlays (e.g., straddles) the remaining portions of the semiconductor structures can be configured as a gate structures (or terminal) of the transistor (or sub-transistor).

For example in FIG. 13, the portion of the active region 1302 that is overlaid by each of the gate structure 1308 may include a number of nanostructures vertically separated from each other, which can function as the channel of a sub-transistor. The portions of the active region 1302 that are disposed on opposite sides of each of the gate structure portion 1308 are replaced with epitaxial structures. Such epitaxial structures can function as source/drain structures of the sub-transistor. The gate structures 1308 can each function as a gate terminal of sub-transistor. Thus, it should be appreciated that the layout 1300 can be used to fabricate a certain number of such sub-transistors. In some embodiments, such sub-transistors, formed based on the patterns 1302-1306 and 1308, can be electrically coupled to each other in parallel to collectively function as the access transistor of an efuse memory cell (e.g., 710 of FIG. 7, 810 of FIG. 8).

The layout 1300 further includes patterns 1310, 1312, 1314, 1316, 1318, 1320, 1322, 1324, 1326, 1328, and 1330 that are each configured to form a metal line (hereinafter “metal line 1310,” “metal line 1312,” “metal line 1314,” “metal line 1316,” metal line 1318,” “metal line 1320,” “metal line 1322,” “metal line 1324,” “metal line 1326,” “metal line 1328,” and “metal line 1330,” respectively). The metal lines 1310 to 1330 may extend along the first lateral direction (e.g., X-direction). The metal lines 1310 to 1330 may each be formed as a metal line disposed in an M0 metallization layer (FIGS. 7-8), e.g., an M0 track. In some embodiments, the metal lines 1310 may operatively serve as an implementation of a WL of the efuse memory cell, sometimes referred to as “WL metal” (through connecting to a gate structure, e.g., 720 or 820, of the access transistor); the metal lines 1312 to 1324 may each be operatively to conduct VSS, sometimes referred to as “VSS metal” (through connecting to one of the source/drain structures, e.g., 716 or 816, of the access transistor); and the metal lines 1326 to 1330 may each be operatively to connect to one end of a corresponding fuse resistor, sometimes referred to as “Vdrain metal” (through connecting to the other of the source/drain structures, e.g., 718 or 818, of the access transistor).

Referring next to FIG. 14, the layout 1400 includes patterns 1402, 1404, 1406, 1408, 1410, 1412, 1414, 1416, 1418, and 1420 that are each configured to form a metal line (hereinafter “metal line 1402,” “metal line 1404,” “metal line 1406,” metal line 1408,” “metal line 1410,” “metal line 1412,” “metal line 1414,” “metal line 1416,” “metal line 1418,” and “metal line 1420,” respectively). The metal lines 1402 to 1420 may extend along the first lateral direction (e.g., X-direction). The metal lines 1402 to 1420 may each be formed as a metal line disposed in an M2 metallization layer (FIGS. 7-8), e.g., an M2 track. In some embodiments, the metal line 1402 may operatively serve as the fuse resistor (e.g., 751 or 851); the metal lines 1404 to 1410 may each operatively serve as the Vdrain metal (i.e., connecting the fuse resistor to the other of the source/drain structures, e.g., 718 or 818, of the access transistor); the metal lines 1412 to 1416 may each operatively serve as the VSS metal (i.e., connecting one of the source/drain structures, e.g., 716 or 816, of the access transistor to VSS); and the metal lines 1418 to 1420 may each be operatively to conduct a programming/reading voltage to the other end of the fuse resistor, sometimes referred to as “VDDQI metal” (through connecting to a peripheral component, e.g., 760 or 870).

Referring again to FIG. 13, in addition to the additional active region compared to the layout 1100 (FIG. 11), the layout 1300 has the M0 tracks 1310 to 1324 arranged asymmetrically with respect to the active regions 1302 to 1306. For example, the VSS metals 1318 and 1320 are each interposed between two of the three active regions 1304 and 1306 along the Y-direction. In comparison, the VSS metals 1124 and 1126 (FIG. 11) are each interposed between the active regions 1102 and 1104 along the Y-direction. As a result, a spacing between the Vdrain metals 1328 and 1330 can be significantly reduced, when compared to a spacing between the Vdrain metals 1116 and 1118 (FIG. 11). This also allows the fuse resistor 1402 (FIG. 14) to be arranged asymmetrically with respect to the active regions 1302 to 1306 as well, which in turn causes multiple such layouts (e.g., 1300) to abut to one another thereby forming an array.

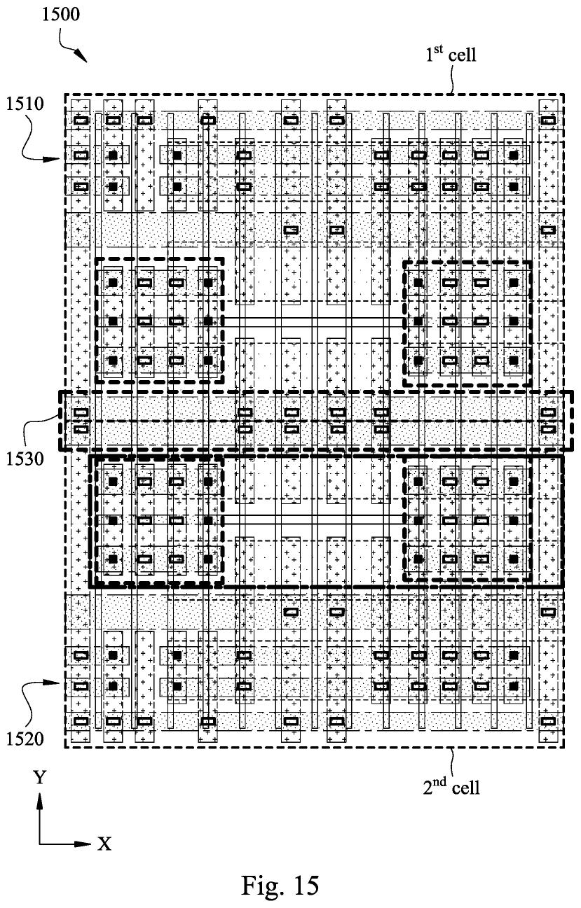

FIG. 15 illustrates an example layout 1500 having two layout components 1510 and 1520 abutted to each other, each of which corresponds to a respective efuse memory cell. In some embodiments, each of the layout components 1510 and 1520 includes a combination of the layouts 1300 and 1400. As shown, the two efuse memory cells (or the layout components 1510 and 1520) share one of the VSS metals, 1530, formed in the M2 metallization layer. Consequently, a plural number of such layouts 1500 can be utilized to form an array having a multiple of two efuse memory cells, while keeping a total height of the array substantially compact.

With the relatively small area of the layout 1500 (e.g., a plural number of the layouts 1300 and 1400), the different portions of a memory array 102 may be grouped into respective sizes (e.g., the layout 400 of FIG. 4), in some embodiments. As the layout size of each efuse memory cell shrinks, the access transistors of the memory cells belonging to the portion 410 that, for example, have the largest threshold voltage can occupy a relatively large size than other portions 420 to 440 in a given area. This is because the access transistors with the relatively large threshold voltage can typically present a smaller leakage current than the access transistors with the relatively small threshold voltage. Thus, with more of such access transistors (with a relatively large threshold voltage) occupying a larger area, a total amount of the leakage current of the whole memory array 102 may be advantageously reduced.

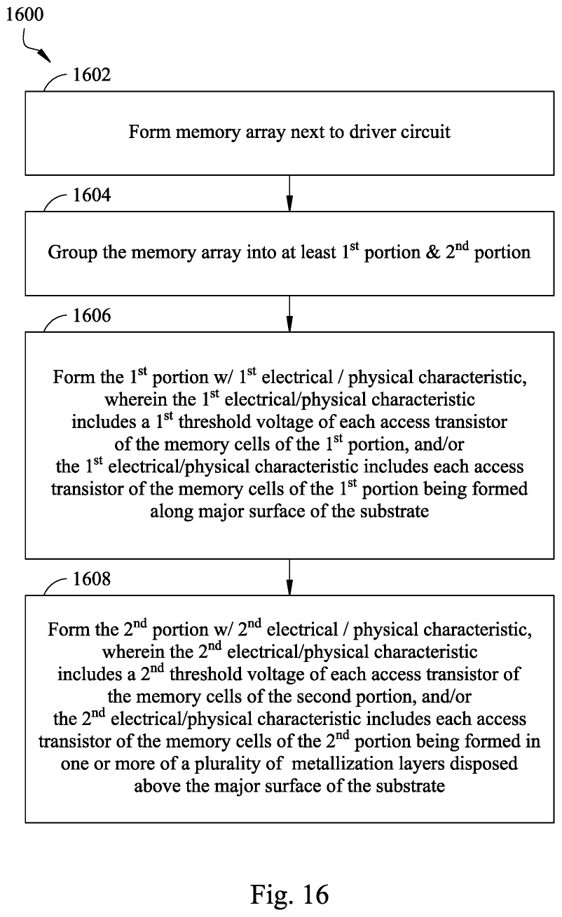

FIG. 16 illustrate a flow chart of an example method 1600 for forming a memory device with a memory array that has plural portions, in accordance with various embodiments. For example, the method 1600 includes operations to fabricate a memory array including at least first portion and a second portion have respectively electrical/physical characteristics (e.g., 310 and 320, 330 and 340, 410 and 420, 430 and 440, 510 and 520). It is noted that the method 1600 is merely an example and is not intended to limit the present disclosure. Accordingly, it is understood that additional operations may be provided before, during, and after the method 1600 of FIG. 16, and that some other operations may only be briefly described herein.

The method 1600 may start with operation 1602 of forming a memory array next to a driver circuit along a lateral direction, where the memory array includes a plurality of memory cells. Using the memory array 102 (FIGS. 1, and 3-5) as an example, the memory array 102 includes a plural number of the memory cells 103, and the memory array 102 is disposed next to the BL driver circuit 106 and the I/O circuit 108 along the Y-direction. The memory cells 103 each include an access transistor (e.g., 204 of FIG. 2, 732 of FIG. 7, 832 of FIG. 8, 862 of FIG. 8) and a fuse resistor (e.g., 202 of FIG. 2, 751 of FIG. 7, 851 of FIG. 8) connected in series. The BL driver 106 and the I/O circuit 108 each include at least one switch/selection transistor (e.g., 734 of FIG. 7, 834 of FIG. 8).

The method 1600 may proceed to operation 1604 of grouping the memory array into at least a first portion and a second portion based on a first distance between the first portion and the driver circuit and a second distance between the second portion and the driver circuit. Continuing with the above example, in FIG. 3, the memory array 102 may be grouped into at least the portions 310 and 320, and the portions 330 and 340; in FIG. 4, the memory array 102 may be grouped into at least the portions 410 and 420, and the portions 430 and 440; and in FIG. 5, the memory array 102 may be grouped into at least the portions 510 and 520. The portion 310 may be closer to the BL driver circuit 106 and the I/O circuit 108 than the portion 320; the portion 330 may be closer to the BL driver circuit 106 and the I/O circuit 108 than the portion 340; the portion 410 may be closer to the BL driver circuit 106 and the I/O circuit 108 than the portion 420; the portion 430 may be closer to the BL driver circuit 106 and the I/O circuit 108 than the portion 440; and the portion 510 may be closer to the BL driver circuit 106 and the I/O circuit 108 than the portion 520.

The method 1600 may proceed to operation 1606 of forming access transistors of the memory cells belonging to the first portion with a first electrical/physical characteristic, and to operation 1608 of forming access transistors of the memory cells belonging to the second portion with a second electrical/physical characteristic. Upon determining the first and second portions, the access transistors of the memory cells belonging to the first portion may be formed with a first electrical/physical characteristic, and the access transistors of the memory cells belonging to the second portion may be formed with a second electrical/physical characteristic.

Using the arrangement 300 of FIG. 3 as a representative example, the access transistors of the memory cells belonging to the portion 310 may be formed with a first threshold voltage, and the access transistors of the memory cells belonging to the portion 320 may be formed with a second threshold voltage. The first threshold voltage is greater than the second threshold voltage. In other words, the near portion of the memory array (e.g., 310) may be associated with a higher threshold voltage than the far portion of the memory array (e.g., 320). It should be understood that the portions 310 and 320 may remain disposed with respect to the BL driver circuit 106 and the I/O circuit 108 by different physical distances, according to such an embodiment. In another example, the access transistors of the memory cells belonging to the portion 310 may be formed in a FEOL network, and the access transistors of the memory cells belonging to the portion 320 may be formed in a BEOL network. The BEOL transistors (of the portion 320) can be formed directly above the FEOL transistors (of the portion 310). In other words, the far portion may be moved to the top of the near portion. It should be understood that the portions 310 and 320 may become being disposed with respect to the BL driver circuit 106 and the I/O circuit 108 by similar physical distances, according to such an embodiment.

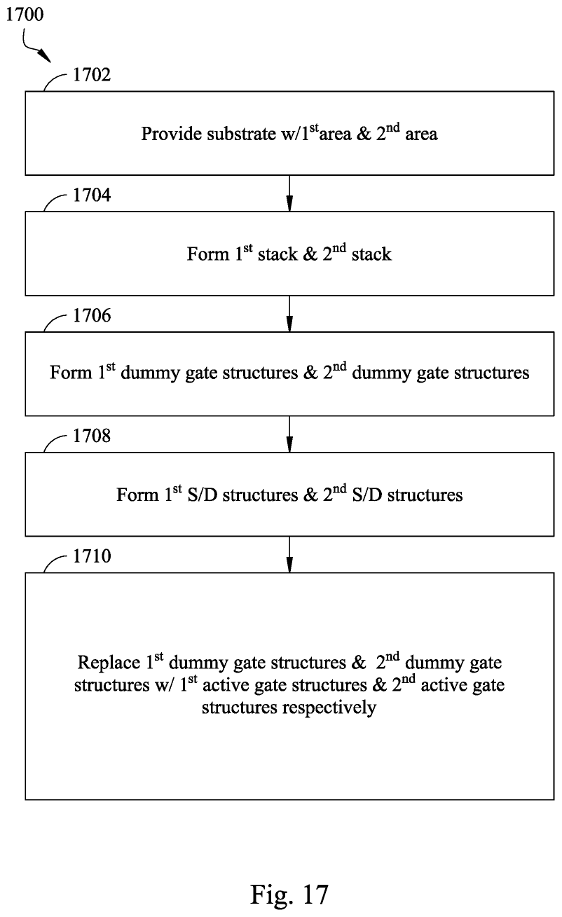

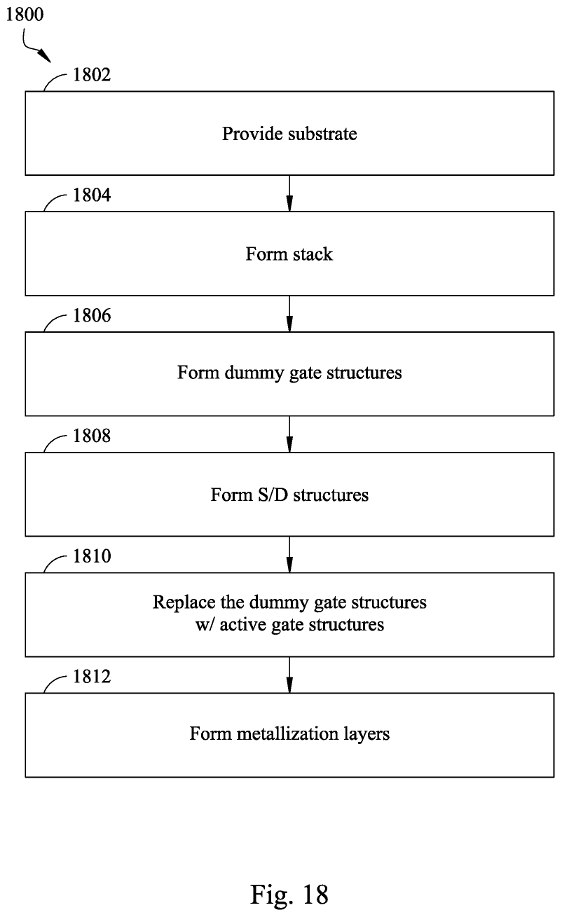

In some embodiments, operations 1606 and 1608 of FIG. 16 can each include multiple fabrication steps, one or more of which may result in forming different electrical/physical characteristics of access transistors corresponding to respective portions of the memory array. For example, operations 1606 and 1608 of FIG. 16 can each include a flow chart shown in FIG. 17 that allows the access transistors in at least the first portion and the second portion of the memory array to have respectively different electrical characteristics. In another example, operations 1606 and 1608 of FIG. 16 can each include a flow chart shown in FIG. 18 that allows the access transistors in at least the first portion and the second portion of the memory array to have respectively different physical characteristics.

Referring first to FIG. 17, a flow chart of an example method 1700 for forming first access transistors and second access transistors (e.g., belonging to the first portion and the second portion of the memory array, respectively) that have different electrical characteristics is shown, in accordance with various embodiments. In some embodiments, the access transistors may each be configured in a GAA FET structure. However, it should be understood that the access transistors each be configured in any of various other transistor structures such as, for example, a planar complementary metal-oxide-semiconductor (CMOS) FET structure, a FinFET structure, etc., while remaining within the scope of the present disclosure. It is noted that the method 1700 is merely an example, and is not intended to limit the present disclosure. Accordingly, it should be understood that additional operations may be provided before, during, and/or after the method 1700, and that some other operations may only be briefly described herein.

The method 1700 starts with operation 1702 of providing a substrate which includes a first area and a second area. The first area and the second area can correspond to the first portion and the second portion of the memory array (e.g., identified in operation 1604 of FIG. 16), respectively. The method 1700 proceeds to operation 1704 of forming a first stack and a second stack in the first area and the second area, respectively. Each of the first and second stacks includes a number of channel layers and a number of sacrificial layers alternatively stacked on top of one another. The method 1700 proceeds to operation 1706 of forming a number of first dummy gate structures traversing the first stack and a number of second dummy gate structures traversing the second stack, respectively. The method 1700 proceeds to operation 1708 of forming first source/drain structures and second source/drain structures in the first stack and the second stack, respectively. The method 1700 proceeds to operation 1710 of replacing the first dummy gate structures and second dummy gate structures with first active gate structures and second active gate structures, respectively.

In some embodiments, the first active gate structures can each correspond to a first gate dielectric thickness, a first flat band voltage, or a first gate dielectric constant; and the second active gate structures can each correspond to a second gate dielectric thickness, a second flat band voltage, or a second gate dielectric constant, in which the first dielectric thickness is different from (e.g., thicker than) the second dielectric thickness, the first flat band voltage is different from (e.g., larger than) the second flat band voltage, or the first gate dielectric constant is different from (e.g., smaller than) the second gate dielectric constant.

Referring first to FIG. 18, a flow chart of an example method 1800 for forming first access transistors and second access transistors (e.g., belonging to the first portion and the second portion of the memory array, respectively) that have different physical characteristics is shown, in accordance with various embodiments. In some embodiments, the access transistors may each be configured in a GAA FET structure. However, it should be understood that the access transistors each be configured in any of various other transistor structures such as, for example, a planar complementary metal-oxide-semiconductor (CMOS) FET structure, a FinFET structure, etc., while remaining within the scope of the present disclosure. It is noted that the method 1800 is merely an example, and is not intended to limit the present disclosure. Accordingly, it should be understood that additional operations may be provided before, during, and/or after the method 1800, and that some other operations may only be briefly described herein.

The method 1800 starts with operation 1802 of providing a substrate. The method 1800 proceeds to operation 1804 of forming a stack that includes a number of channel layers and a number of sacrificial layers alternatively stacked on top of one another. The method 1800 proceeds to operation 1806 of forming a number of dummy gate structures traversing the stack. The method 1800 proceeds to operation 1808 of forming source/drain structures in the stack. The method 1800 proceeds to operation 1810 of replacing the dummy gate structures with active gate structures. In some embodiments, after forming the active gate structures, a number of access transistors, corresponding to the first portion of the memory array, can be formed along a major (e.g., frontside) surface of the substrate. The method 1800 proceeds to operation 1812 of forming multiple metallization layers above the major surface of the substrate. Each of the metallization layers includes a respective number of metal lines. In some embodiments, a number of access transistors, corresponding to the second portion of the memory array, can be formed between adjacent ones of these metallization layers.

In one aspect of the present disclosure, a memory device is disclosed. The memory device includes a memory array including a plurality of memory cells, each of the memory cells including an access transistor and a fuse resistor coupled to each other in series; a first driver circuit disposed next to the memory array along a first lateral direction and operatively coupled to the access transistor of each of the memory cells; and a second driver circuit disposed next to the memory array along a second lateral direction and operatively coupled to the fuse resistor of each of the memory cells. The memory array consists of a plurality of portions. The access transistors of the memory cells belonging to at least a first one of the plurality of portions have a first electrical characteristic or are disposed along a major surface of a substrate. The access transistors of the memory cells belonging to at least a second one of the plurality of portions have a second electrical characteristic different from the first electrical characteristic or are disposed in one or more of a plurality of metallization layers disposed above the major surface of the substrate. The first electrical characteristic includes at least one of: a first gate dielectric thickness, a first doping concentration, a first flat band voltage, or a first gate dielectric constant, and the second electrical characteristic includes at least one of: a second gate dielectric thickness, a second doping concentration, a second flat band voltage, or a second gate dielectric constant.

In another aspect of the present disclosure, a memory device is disclosed. The memory device includes a plurality of one-time-programming (OTP) memory cells grouped at least into a first portion and a second portion, wherein the first and second portions are disposed next to each other along a first lateral direction; a first driver circuit disposed next to the first portion along a first lateral direction, wherein the first portion is interposed between the second portion and the first driver circuit along the first lateral direction; and a second driver circuit disposed next to both of the first and second portions along a second lateral direction perpendicular to the first lateral direction. The OTP memory cells of the first portion are associated with a first electrical/physical characteristic and the OTP memory cells of the second portion are associated with a second electrical/physical characteristic, in which the first electrical/physical characteristic is different from the second electrical/physical characteristic.

In yet another aspect of the present disclosure, a method for fabricating memory devices is disclosed. The method includes forming a memory array next to a driver circuit along a lateral direction, the memory array including a plurality of memory cells. The method includes grouping the memory array into at least a first portion and a second portion based on a first distance between the first portion and the driver circuit and a second distance between the second portion and the driver circuit. The method includes forming access transistors of a first subset of the memory cells belonging to the first portion that have a first electrical characteristic or a first physical characteristic. The method includes forming access transistors of a second subset of the memory cells belonging to the second portion that have a second electrical characteristic different from the first electrical characteristic or a second physical characteristic different from the second physical characteristic. Each of the plurality of memory cells is configured as a one-time-programmable (OTP) memory cell that further includes a fuse resistor formed in a corresponding one of a plurality of metallization layers disposed above a major surface of a substrate.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a memory array including a plurality of memory cells, each of the memory cells including an access transistor and a fuse resistor coupled to each other in series;
a first driver circuit disposed next to the memory array along a first lateral direction and operatively coupled to the access transistor of each of the memory cells; and
a second driver circuit disposed next to the memory array along a second lateral direction and operatively coupled to the fuse resistor of each of the memory cells;
wherein the memory array consists of a plurality of portions;
wherein the access transistors of the memory cells belonging to at least a first one of the plurality of portions have a first electrical characteristic or are disposed along a major surface of a substrate;
wherein the access transistors of the memory cells belonging to at least a second one of the plurality of portions have a second electrical characteristic different from the first electrical characteristic or are disposed in one or more of a plurality of metallization layers disposed above the major surface of the substrate; and
wherein the first electrical characteristic includes at least one of: a first gate dielectric thickness, a first doping concentration, a first flat band voltage, or a first gate dielectric constant, and the second electrical characteristic includes at least one of: a second gate dielectric thickness, a second doping concentration, a second flat band voltage, or a second gate dielectric constant.

2. The memory device of claim 1, wherein the second portion is disposed next to the first driver circuit along the first lateral direction or next to the second driver circuit along the second lateral direction, with the first portion interposed therebetween.

3. The memory device of claim 2, wherein the first electrical characteristic results in a first threshold voltage and the second electrical characteristic results in a second threshold voltage, and wherein the first threshold voltage is higher than the second threshold voltage.

4. The memory device of claim 2, wherein the second portion is disposed next to the first driver circuit along the first lateral direction with the first portion interposed therebetween, the memory device further comprises:
a plurality of input/output circuits each formed of a plurality of transistors that are also disposed along the major surface of the substrate;
wherein the plurality of input/output circuits are disposed next to the first portion with the first driver circuit interposed therebetween along the first lateral direction.

5. The memory device of claim 4, wherein the access transistors of the memory cells belonging to the first portion are disposed along the major surface of the substrate while the access transistors of the memory cells belonging to the second portion are disposed in the one or more metallization layers, such that a first distance extending from an interconnect structure disposed in a corresponding one of the metallization layers to the fuse resistors of the memory cells belonging to the first portion is approximately equal to a second distance extending from the interconnect structure to the fuse resistors of the memory cells belonging to the second portion.

6. The memory device of claim 5, wherein the interconnect structure is configured to operatively couple the input/output circuits to the fuse resistors of the memory cells belonging to the first portion, and to the fuse resistors of the memory cells belonging to the second portion.

7. The memory device of claim 2, wherein the access transistors of the memory cells belonging to a third one of the plurality of portions have a third electrical characteristic different from any of the first or second electrical characteristic.

8. The memory device of claim 7, wherein the third portion is disposed next to the first driver circuit along the first lateral direction, with the second portion interposed therebetween.

9. The memory device of claim 8, wherein the first electrical characteristic results in a first threshold voltage, the second electrical characteristic results in a second threshold voltage, and the third electrical characteristic results in a third threshold voltage, and wherein the first threshold voltage is higher than the second threshold voltage and the second threshold voltage is higher than the third threshold voltage.

10. The memory device of claim 8, wherein the first portion has a first size, the second portion has a second size, and the third portion has a third size, in which the first to third sizes are equal to one another.

11. The memory device of claim 8, wherein the first portion has a first size, the second portion has a second size, and the third portion has a third size, in which the first size is larger than the second size and the second size is larger than the third size.

12. A memory device, comprising:
a plurality of one-time-programming (OTP) memory cells grouped at least into a first portion and a second portion, wherein the first and second portions are disposed next to each other along a first lateral direction;
a first driver circuit disposed next to the first portion along a first lateral direction, wherein the first portion is interposed between the second portion and the first driver circuit along the first lateral direction; and
a second driver circuit disposed next to both of the first and second portions along a second lateral direction perpendicular to the first lateral direction;
wherein the OTP memory cells of the first portion are associated with a first electrical/physical characteristic and the OTP memory cells of the second portion are associated with a second electrical/physical characteristic, in which the first electrical/physical characteristic is different from the second electrical/physical characteristic.

13. The memory device of claim 12,
wherein the first electrical/physical characteristic includes a first threshold voltage of each access transistor of the OTP memory cells of the first portion, and the second electrical/physical characteristic includes a second threshold voltage of each access transistor of the OTP memory cells of the second portion; and
wherein the first threshold voltage is higher than the second threshold voltage.

14. The memory device of claim 12,
wherein the first electrical/physical characteristic includes each access transistor of the OTP memory cells of the first portion being formed along a major surface of a substrate; and
wherein the second electrical/physical characteristic includes each access transistor of the OTP memory cells of the second portion being formed in one or more of a plurality of metallization layers disposed above the major surface of the substrate.

15. The memory device of claim 14, further comprising:
a plurality of input/output circuits each formed of a plurality of transistors that are also disposed along the major surface of the substrate;
wherein the plurality of input/output circuits are disposed next to the first portion with the first driver circuit interposed therebetween along the first lateral direction.

16. The memory device of claim 15, wherein a first distance extending from an interconnect structure disposed in a corresponding one of the metallization layers to fuse resistors of the OTP memory cells of the first portion is approximately equal to a second distance extending from the interconnect structure to fuse resistors of the OTP memory cells of the second portion.

17. The memory device of claim 12, wherein the first portion has a first size and the second portion has a second size, in which the first size is equal to or larger than the second size.

18. A method for forming a memory device, comprising:
forming a memory array next to a driver circuit along a lateral direction, the memory array including a plurality of memory cells;
grouping the memory array into at least a first portion and a second portion based on a first distance between the first portion and the driver circuit and a second distance between the second portion and the driver circuit;
forming access transistors of a first subset of the memory cells belonging to the first portion that have a first electrical characteristic or a first physical characteristic; and
forming access transistors of a second subset of the memory cells belonging to the second portion that have a second electrical characteristic different from the first electrical characteristic or a second physical characteristic different from the first physical characteristic;
wherein each of the plurality of memory cells is configured as a one-time-programmable (OTP) memory cell that further includes a fuse resistor formed in a corresponding one of a plurality of metallization layers disposed above a major surface of a substrate.

19. The method of claim 18, wherein the first distance is shorter than the second distance, and the first electrical characteristic causes the access transistors of the first subset of memory cells to have a first threshold voltage and the second electrical characteristic causes the access transistors of the second subset of memory cells to have a second threshold voltage, in which the first threshold voltage is higher than the second threshold voltage.

20. The method of claim 18, wherein the first distance is shorter than the second distance, and the first physical characteristic includes the access transistors of the first subset of memory cells being formed along the major surface of the substrate and the second physical characteristic includes the access transistors of the second subset of memory cells being formed among the metallization layers.
